(19) United States
(12) Patent Application Publication
(10) Pub. No.: US 2026/0213778 A1
(43) Pub. Date: Jul. 23, 2026

(54) FILTER SWITCHING CIRCUIT

(71) Applicant: Murata Manufacturing Co., Ltd., Nagaokakyo-shi (JP)

(72) Inventors: Yuito SAWAYAMA, Nagaokakyo-sh (JP); Tomoya ODA, Nagaokakyo-shi (JP); Tetsurou ASHIDA, Nagaokakyo-shi (JP)

(21) Appl. No.: 19/453,198

(22) Filed: Jan. 20, 2026

(30) Foreign Application Priority Data
Jan. 20, 2025 (JP) 2025-007948

(51) Int. Cl. H04B 1/04; H03F 1/02

(52) U.S. Cl. CPC H04B 1/04; H03F 1/0283; H03F 2200/09; H03F 2200/165; H03F 2200/451; H03F 2201/3215; H04B 2001/045

(57) ABSTRACT

A filter switching circuit includes: a first node supplied with a first amplified signal in a first radio frequency band in a first mode; a second node that is supplied, in the first mode, with a second amplified signal in the first radio frequency band having a phase identical to a phase of the first amplified signal and that is supplied, in a second mode, with a third amplified signal in a second radio frequency band; a semiconductor switching element including a first end connected to the first node and a second end connected to the second node; a first semiconductor switching circuit including a first common terminal connected to the second node and first individual terminals; a second semiconductor switching circuit including a second common terminal connected to a first output terminal.

### CROSS REFERENCE TO RELATED APPLICATION

This application claims priority from Japanese Patent Application No. 2025-007948, filed on January 20, 2025. The content of this application is incorporated herein by reference in its entirety.

### BACKGROUND OF THE DISCLOSURE

### 1. Field of the Disclosure

The present disclosure relates to a filter switching circuit.

### 2. Description of the Related Art

There are wireless devices including a power amplifier, a switch-multiplexer, a filter, and an antenna interface circuit (for example, see Japanese Unexamined Patent Application Publication (Translation of PCT Application No. 2015-508268)). In a wireless device described in Japanese Unexamined Patent Application Publication (Translation of PCT Application No. 2015-508268), a switch-multiplexer includes a power amplifier connected to output of a plurality of switches. A subset of the plurality of switches is connected to an antenna interface circuit with a corresponding subset of a plurality of filters interposed therebetween. A different subset of the plurality of switches is connected to the antenna interface circuit with a bypass path provided in parallel to the plurality of filters interposed therebetween.

### BRIEF SUMMARY OF THE DISCLOSURE

In the configuration of the wireless device described in Japanese Unexamined Patent Application Publication (Translation of PCT Application No. 2015-508268), a radio frequency (RF) signal outputted from the power amplifier is transmitted to one of the filters or the bypass path via a corresponding one of the switches included in the switch-multiplexer. Power loss occurs when the RF signal passes through the switch, and thus a configuration in which the power loss is reduced is desirable.

The present disclosure has been made under the circumstances as described above, and it is a possible benefit of the present disclosure to provide a filter switching circuit capable of reducing power loss in a radio frequency signal.

A filter switching circuit according to an aspect of the present disclosure includes: a first node supplied with a first amplified signal in a first radio frequency band in a first mode; a second node that is supplied, in the first mode, with a second amplified signal in the first radio frequency band having a phase identical to a phase of the first amplified signal and that is supplied, in a second mode, with a third amplified signal in a second radio frequency band; a semiconductor switching element including a first end connected to the first node and a second end connected to the second node, the semiconductor switching element performing switching between electrical connection and non-connection between the first end and the second end; a first semiconductor switching circuit including a first common terminal connected to the second node and first individual terminals a count of which is M (an integer of 2 or greater), the first semiconductor switching circuit performing switching between electrical connection and non-connection between the first common terminal and any one of the M first individual terminals; a second semiconductor switching circuit including a second common terminal connected to a first output terminal, M second individual terminals respectively connected to the M first individual terminals through M first wiring lines, and a third individual terminal connected to the first node through a second wiring line, the second semiconductor switching circuit performing switching between electrical connection and non-connection between the second common terminal and any one of the M second individual terminals or the third individual terminal; M first filters respectively provided on the M first wiring lines; and a second filter provided on the second wiring line.

A filter switching circuit according to another aspect of the present disclosure includes: a first node supplied with a first amplified signal in a first radio frequency band in a first mode; a second node that is supplied, in the first mode, with a second amplified signal in the first radio frequency band having a phase identical to a phase of the first amplified signal and that is supplied, in a second mode, with a third amplified signal in a second radio frequency band; a semiconductor switching element including a first end connected to the first node and a second end connected to the second node, the semiconductor switching element performing switching between electrical connection and non-connection between the first end and the second end; a first semiconductor switching circuit including a first common terminal connected to the second node and first individual terminals a count of which is M (an integer of 2 or greater), the first semiconductor switching circuit performing switching between electrical connection and non-connection between the first common terminal and any one of the M first individual terminals; a second semiconductor switching circuit including a fourth common terminal connected to a third wiring line, M second individual terminals respectively connected to the M first individual terminals through M first wiring lines, a third individual terminal connected to the first node through a second wiring line, a fifth common terminal connected to a fourth wiring line, the second semiconductor switching circuit performing switching between electrical connection and non-connection between the fourth common terminal and any one of the M second individual terminals, the second semiconductor switching circuit also performing switching between electrical connection and non-connection between the fifth common terminal and either at least one of the M second individual terminals or the third individual terminal; M first filters respectively provided on the M first wiring lines; and a second filter provided on the fourth wiring line.

A filter switching circuit according to another aspect of the present disclosure includes: a first node supplied with a first amplified signal in a first radio frequency band in a first mode; a second node that is supplied, in the first mode, with a second amplified signal in the first radio frequency band having a phase identical to a phase of the first amplified signal and that is supplied, in a second mode, with a third amplified signal in a second radio frequency band; a semiconductor switching element including a first end connected to the first node and a second end connected to the second node, the semiconductor switching element performing switching between electrical connection and non-connection between the first end and the second end; a first semiconductor switching circuit including a first common terminal connected to the second node and first individual terminals a count of which is M (an integer of 2 or greater), the first semiconductor switching circuit performing switching between electrical connection and non-connection between the first common terminal and any one of the M first individual terminals; a second semiconductor switching circuit including a seventh common terminal connected to a first output terminal, M second individual terminals respectively connected to the M first individual terminals through M first wiring lines, a third individual terminal connected to the first node through a second wiring line, a sixth individual terminal, an eighth common terminal connected to the sixth individual terminal through a fifth wiring line, the second semiconductor switching circuit performing switching between electrical connection and non-connection between the seventh common terminal and any one of the M second individual terminals or the sixth individual terminal, the second semiconductor switching circuit also performing switching between electrical connection and non-connection between the eighth common terminal and either at least one of the M second individual terminals or the third individual terminal; M first filters respectively provided on the M first wiring lines; and a second filter provided on the fifth wiring line.

The present disclosure may provide a filter switching circuit capable of reducing power loss in a radio frequency signal.

### BRIEF DESCRIPTION OF THE SEVERAL VIEWS OF THE DRAWINGS

FIG. 1 is a circuit diagram of a power amplifier circuit 101;

FIG. 2 is a view illustrating an example of connection states of the semiconductor switching circuits at the time when the power amplifier circuit 101 operates in a power-prioritized mode M1;

FIG. 3 is a view illustrating an example of connection states of the semiconductor switching circuits at the time when the power amplifier circuit 101 operates in an efficiency-prioritized mode M2;

FIG. 4 is a circuit diagram of a power amplifier circuit 102;

FIG. 5 is a view illustrating an example of connection states of semiconductor switching circuits at the time when the power amplifier circuit 102 operates in the power-prioritized mode M1;

FIG. 6 is a view illustrating an example of connection states of the semiconductor switching circuits at the time when the power amplifier circuit 102 operates in the efficiency-prioritized mode M2;

FIG. 7 is a circuit diagram of a power amplifier circuit 103;

FIG. 8 is a view illustrating an example of connection states of semiconductor switching circuits at the time when the power amplifier circuit 103 operates in the power-prioritized mode M1;

FIG. 9 is a view illustrating an example of connection states of the semiconductor switching circuits at the time when the power amplifier circuit 103 operates in the efficiency-prioritized mode M2;

FIG. 10 is a view illustrating an example of connection states of the semiconductor switching circuits at the time when the power amplifier circuit 103 operates in the efficiency-prioritized mode M2;

FIG. 11 is a graph illustrating an example of simulation results of amplification characteristics in the power amplifier circuit 103;

FIG. 12 is an enlarged graph of the amplification characteristics at zero to 1.5 GHz in the simulation results illustrated in FIG. 11;

FIG. 13 is a circuit diagram of a power amplifier circuit 104;

FIG. 14 is a view illustrating an example of connection states of the semiconductor switching circuits at the time when the power amplifier circuit 104 operates in the power-prioritized mode M1;

FIG. 15 is a view illustrating an example of connection states of the semiconductor switching circuits at the time when the power amplifier circuit 104 operates in the efficiency-prioritized mode M2; and

FIG. 16 is a view illustrating an example of connection states of the semiconductor switching circuits at the time when the power amplifier circuit 104 operates in the efficiency-prioritized mode M2.

### DETAILED DESCRIPTION OF THE DISCLOSURE

Hereinafter, embodiments of the present disclosure will be described in detail with reference to the drawings. The same elements are denoted by the same reference numerals, and overlapping explanation is omitted as much as possible.

### First Embodiment

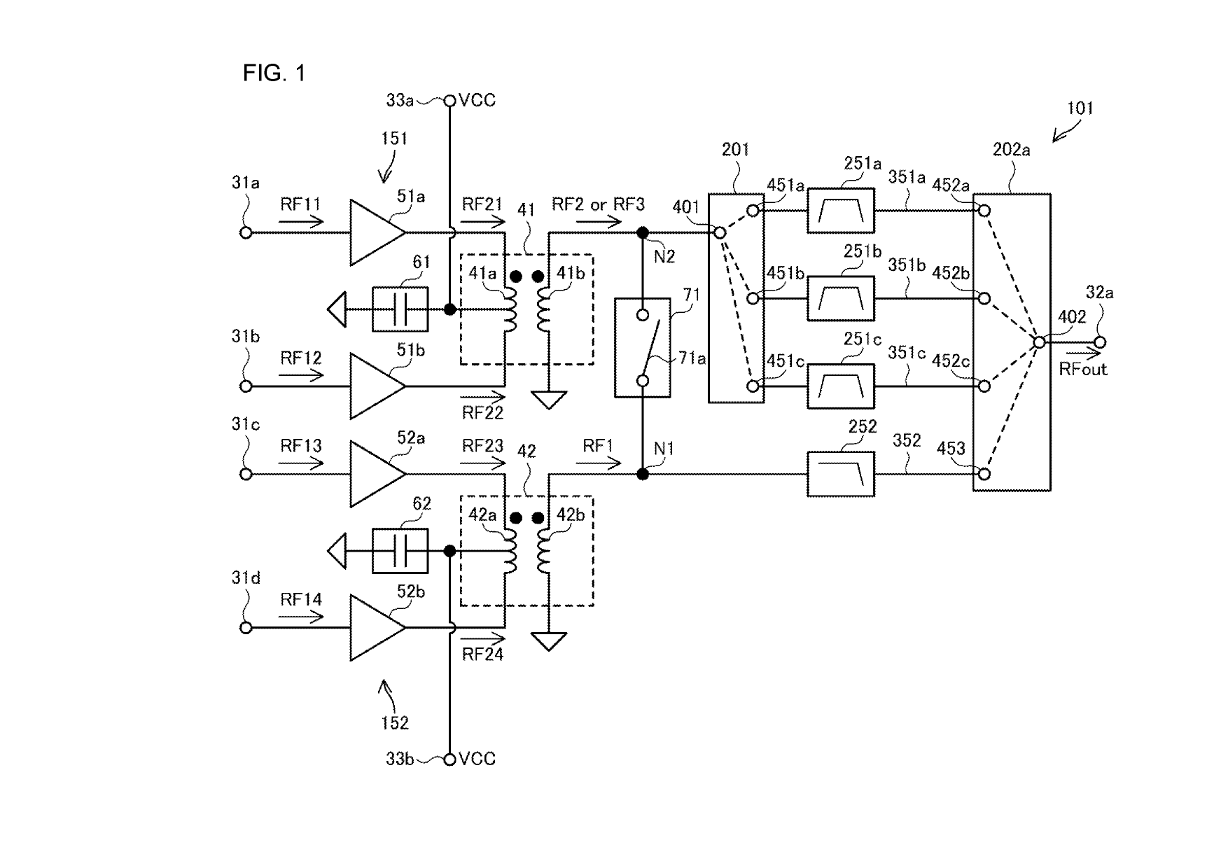

A power amplifier circuit 101 according to a first embodiment will be described. FIG. 1 is a circuit diagram of the power amplifier circuit 101. As illustrated in FIG. 1, the power amplifier circuit 101 is an amplifier circuit that is provided in a front-end module, that amplifies an input signal supplied to the input terminal (not illustrated), and that outputs an output signal RFout from an output terminal 32a (first output terminal). The output terminal 32a is an antenna terminal connected to, for example, an antenna.

A RF signal in a radio frequency band (first radio frequency band) (hereinafter, also referred to as a 2G band) specified in communication standards for, for example, a second-generation mobile communication system (2G) and an RF signal in a radio frequency band (second radio frequency band) (hereinafter, also referred to as a 5G band) specified in communication standards for the fifth-generation mobile communication system (5G) serve as the input signal supplied to the input terminal. The second radio frequency band is not limited to the radio frequency band specified in the communication standards for the fifth-generation mobile communication system (5G) and may be a radio frequency band specified in communication standards for a fourth-generation mobile communication system (4G) or a radio frequency band specified in communication standards for a sixth-generation mobile communication system (6G).

When a RF signal in the 2G band is supplied to an input terminal, the power amplifier circuit 101 operates in a power-prioritized mode M1 (first mode). In contrast, when a RF signal in the 5G band is supplied to the input terminal, the power amplifier circuit 101 operates in an efficiency-prioritized mode M2 (second mode).

The frequency band of the RF signal in the 2G band and the frequency band of the RF signal in the 5G band are included in a low band (LB) that is a frequency band, for example, from 660 MHz to 920 MHz.

The power amplifier circuit 101 (a filter switching circuit) includes baluns 41 and 42, capacitors 61 and 62, a semiconductor switching circuit 71, differential pairs 151 and 152, semiconductor switching circuits 201 (first semiconductor switching circuit) and 202a (second semiconductor switching circuit), filter circuits 251 (first filters) the number of which is M (an integer of 2 or greater), a filter circuit 252 (second filter), and nodes N1 (first node) and N2 (second node).

In this embodiment, M is 3. M may be 2 and 4 or greater, as an integer. Hereinafter, the M (for example, three) respective filter circuits 251 are referred to as filter circuits 251a, 251b, and 251c on occasions.

The filter circuits 251 are band pass filters used, for example, for the RF signal in the 5G band. The filter circuit 252 is a low pass filter used for attenuating a harmonic wave of, for example, the RF signal in the 2G band.

The differential pair 151 includes power-stage amplifiers 51a and 51b. The differential pair 152 includes power-stage amplifiers 52a and 52b.

In this embodiment, the power-stage amplifiers 51a, 51b, 52a, and 52b are formed by using bipolar transistors such as a heterojunction bipolar transistor (HBT). The amplifier may also be formed by using different transistors such as field effect transistors (metal-oxide-semiconductor field-effect transistors (MOSFETs)). In this case, a base, a collector, and an emitter may respectively be read as a gate, a drain, and a source.

Amplified signals RF11 and RF12 that are balanced signals are respectively supplied to terminals 31a and 31b. Amplified signals RF13 and RF14 that are balanced signals are respectively supplied to terminals 31c and 31d.

The phase of the amplified signal RF11 differs from the phase of the amplified signal RF12 by substantially 180 degrees. Wiring length imbalance or the like in the circuit causes a difference between the circuit and the phase of the amplified signal RF11 to largely differ from the phase of the amplified signal RF12 in some cases.

The phase of the amplified signal RF13 differs from the phase of the amplified signal RF14 by substantially 180 degrees. Wiring length imbalance or the like in the circuit causes a difference between the circuit and the phase of the amplified signal RF13 to largely differ from the phase of the amplified signal RF14 in some cases.

The phase of the amplified signal RF11 is substantially the same as the phase of the amplified signal RF13. Wiring length imbalance or the like in the circuit causes a difference between the circuit and the phase of the amplified signal RF11 to largely differ from the phase of the amplified signal RF13 in some cases.

The phase of the amplified signal RF12 is substantially the same as the phase of the amplified signal RF14. Wiring length imbalance or the like in the circuit causes a difference between the circuit and the phase of the amplified signal RF12 to largely differ from the phase of the amplified signal RF14 in some cases.

The amplified signals RF11, RF12, RF13, and RF14 are generated based on an input signal supplied to the corresponding input terminal.

Specifically, for example, a driver-stage amplifier (not illustrated) amplifies an input signal, and thereby an unbalanced signal is generated. The unbalanced signal is converted, for example, by a balun, to one of the amplified signals RF11 and RF12 that are the balanced signals and the amplified signals RF13 and RF14 that are the balanced signals.

In the differential pair 151, the power-stage amplifiers 51a and 51b operate in one of the power-prioritized mode M1 and the efficiency-prioritized mode M2. More specifically, in the power-prioritized mode M1 and the efficiency-prioritized mode M2, a bias voltage higher than a threshold voltage is applied to one of the bases of the power-stage amplifiers 51a and 51b, and the power-stage amplifier 51a or 51b enters an on state.

Based on a supply voltage VCC applied from a power supply terminal 33a via the balun 41, the power-stage amplifier 51a amplifies the amplified signal RF11 supplied via the terminal 31a and outputs an amplified signal RF21.

Based on the supply voltage VCC applied from the power supply terminal 33a via the balun 41, the power-stage amplifier 51b amplifies the amplified signal RF12 supplied via the terminal 31b and outputs an amplified signal RF22.

In the differential pair 152, the power-stage amplifiers 52a and 52b operate in the power-prioritized mode M1 but do not operate in the efficiency-prioritized mode M2. More specifically, in the efficiency-prioritized mode M2, a bias voltage applied to the base of one of the power-stage amplifiers 52a and 52b becomes substantially zero volts, and the power-stage amplifier 52a or 52b enters an off state. In contrast, in the power-prioritized mode M1, a bias voltage higher than the threshold voltage is applied to the base of one of the power-stage amplifiers 52a and 52b, and the power-stage amplifier 52a or 52b enters the on state.

Based on the supply voltage VCC applied from a power supply terminal 33b via the balun 42, the power-stage amplifier 52a amplifies the amplified signal RF13 supplied via the terminal 31c and outputs an amplified signal RF23.

Based on the supply voltage VCC applied from the power supply terminal 33b via the balun 42, the power-stage amplifier 52b amplifies the amplified signal RF14 supplied via the terminal 31d and outputs an amplified signal RF24.

In the power-prioritized mode M1, the balun 41 generates an amplified signal RF2 (second amplified signal) that is an unbalanced signal from one of the amplified signals RF21 and RF22 that are balanced signals. In the efficiency-prioritized mode M2, the balun 41 generates an amplified signal RF3 (third amplified signal) that is an unbalanced signal from the amplified signals RF21 and RF22 that are the balanced signals.

More specifically, the balun 41 includes inductors 41a and 41b. The inductor 41a has a first end, an intermediate tap, and a second end. The first end is connected to the output terminal of the power-stage amplifier 51a and is supplied with the amplified signal RF21. The intermediate tap is connected to the power supply terminal 33a and also connected to ground with the capacitor 61 interposed therebetween. The second end is connected to the output terminal of the power-stage amplifier 51b and is supplied with the amplified signal RF22.

The inductor 41b is electromagnetically coupled to the inductor 41a. The inductor 41b has a first end and a second end. The first end respectively outputs the amplified signal RF2 and the amplified signal RF3 in the power-prioritized mode M1 and the efficiency-prioritized mode M2 and is connected to the node N2. The second end is connected to ground.

The balun 42 generates an amplified signal RF1 (first amplified signal) that is an unbalanced signal from the amplified signals RF23 and RF24 that are balanced signals in the power-prioritized mode M1. In contrast, the balun 42 does not output a signal in the efficiency-prioritized mode M2.

More specifically, the balun 42 includes inductors 42a and 42b. The inductor 42a has a first end, an intermediate tap, and a second end. The first end is connected to the output terminal of the power-stage amplifier 52a and is supplied with the amplified signal RF23. The intermediate tap is connected to the power supply terminal 33b and is also connected to ground with the capacitor 62 interposed therebetween. The second end is connected to the output terminal of the power-stage amplifier 52b and is supplied with the amplified signal RF24.

The inductor 42b is electromagnetically coupled to the inductor 42a. The inductor 42b has a first end and a second end, the first end outputting the amplified signal RF1 in the power-prioritized mode M1 and being connected to the node N1, the second end being connected to ground.

The semiconductor switching circuit 71 includes a semiconductor switching element 71a. The semiconductor switching element 71a has a first end connected to the node N1 and a second end connected to the node N2.

The semiconductor switching element 71a performs switching between electrical connection and non-connection between the first end and the second end.

The semiconductor switching circuit 201 has a common terminal 401 (first common terminal) connected to the node N2 and individual terminals 451 (first individual terminal) the number of which is M (for example, 3). Hereinafter, the respective individual terminals 451 the number of which is, for example, 3 are referred to as individual terminals 451a, 451b, and 451c on occasions.

The semiconductor switching circuit 201 performs switching between electrical connection and non-connection between the common terminal 401 and any one of the individual terminals 451a, 451b, and 451c.

The semiconductor switching circuit 202a has a common terminal 402 (second common terminal) connected to the output terminal 32a, individual terminals 452 (second individual terminals) the number of which is M (for example, 3) respectively connected to the M individual terminals 451 through transmission lines 351 (first wiring lines) the number of which is M, and an individual terminal 453 (third individual terminal) connected to the node N1 through a transmission line 352 (second wiring line).

Hereinafter, the respective transmission lines 351 the number of which is, for example, 3 are referred to as transmission lines 351a, 351b, and 351c on occasions. The respective individual terminals 452 the number of which is, for example, 3 are referred to as individual terminals 452a, 452b, and 452c on occasions.

In this embodiment, the individual terminals 452a, 452b, and 452c are respectively connected to the individual terminals 451a, 451b, and 451c in the semiconductor switching circuit 201 through the transmission lines 351a, 351b, and 351c.

The semiconductor switching circuit 202a performs switching between the electrical connection and the non-connection between the common terminal 402 and any one of the individual terminals 452a, 452b, 452c, and 453.

The filter circuits 251 the number of which is M (for example, 3) are respectively provided on the M transmission lines 351. Hereinafter, the respective filter circuits 251 the number of which is, for example, 3 are referred to as the filter circuits 251a, 251b, and 251c on occasions.

In this embodiment, the filter circuits 251a, 251b, and 251c are respectively provided on the transmission lines 351a, 351b, and 351c. The filter circuit 252 is provided on the transmission line 352.

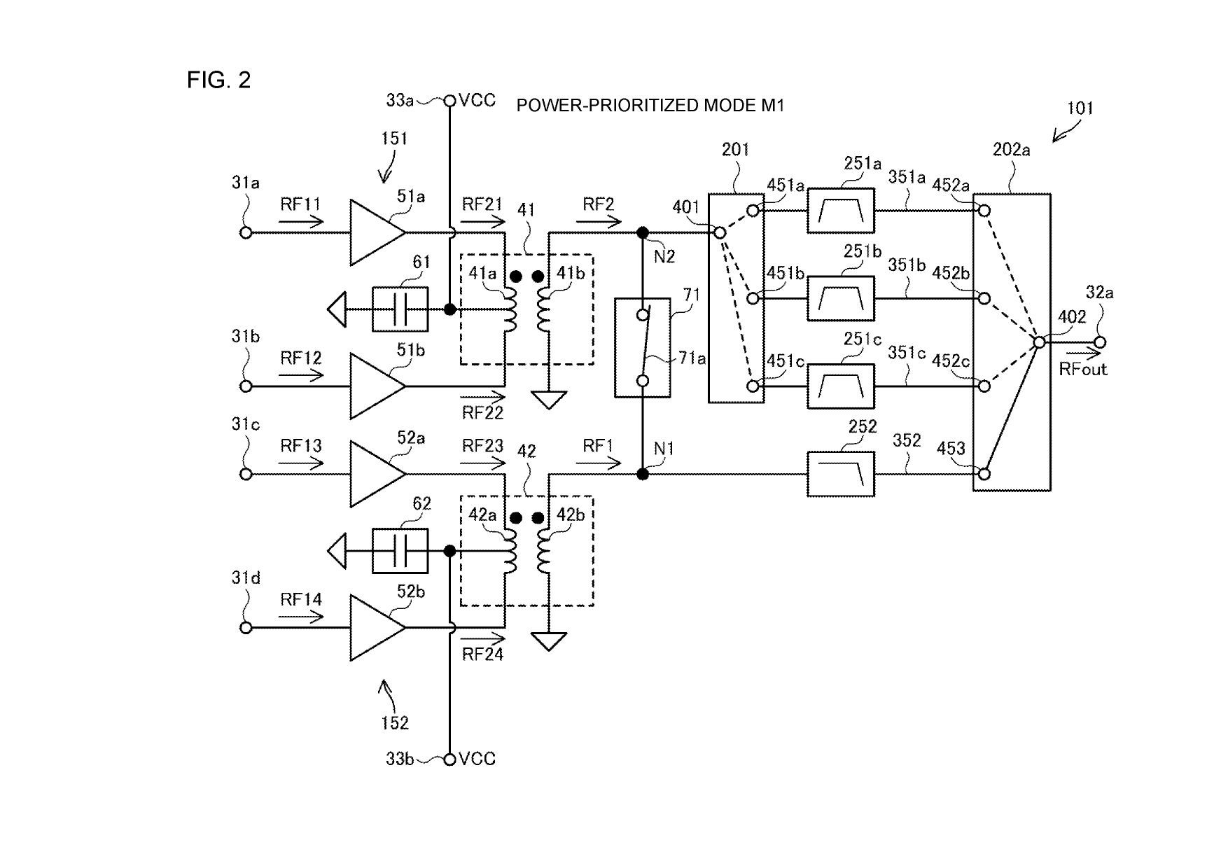

FIG. 2 is a view illustrating an example of connection states of the semiconductor switching circuits at the time when the power amplifier circuit 101 operates in the power-prioritized mode M1. As illustrated in FIG. 2, the semiconductor switching element 71a electrically connects the first end and the second end in the power-prioritized mode M1.

The semiconductor switching circuits 201 and 202a do not electrically connect the common terminal 401 and the common terminal 402 in the power-prioritized mode M1.

More specifically, the semiconductor switching circuit 201 may be in a non-connection state in which the common terminal 401 and the individual terminals 451a, 451b, and 451c are not electrically connected, the semiconductor switching circuit 202a may be in a non-connection state in which the common terminal 402 and the individual terminals 452a, 452b, and 452c are not electrically connected, and both of the semiconductor switching circuits 201 and 202a may be in the non-connection state.

The semiconductor switching circuit 202a electrically connects the common terminal 402 and the individual terminal 453 in the power-prioritized mode M1.

The amplified signal RF1 supplied from the first end of the inductor 42b and the amplified signal RF2 supplied from the first end of the inductor 41b via the semiconductor switching element 71a are thereby combined at the node N1. The amplified signal thus combined passes through the filter circuit 252 as well as the individual terminal 453 and the common terminal 402 in the semiconductor switching circuit 202a and is outputted from the output terminal 32a to the circuit at the subsequent stage, for example, the antenna.

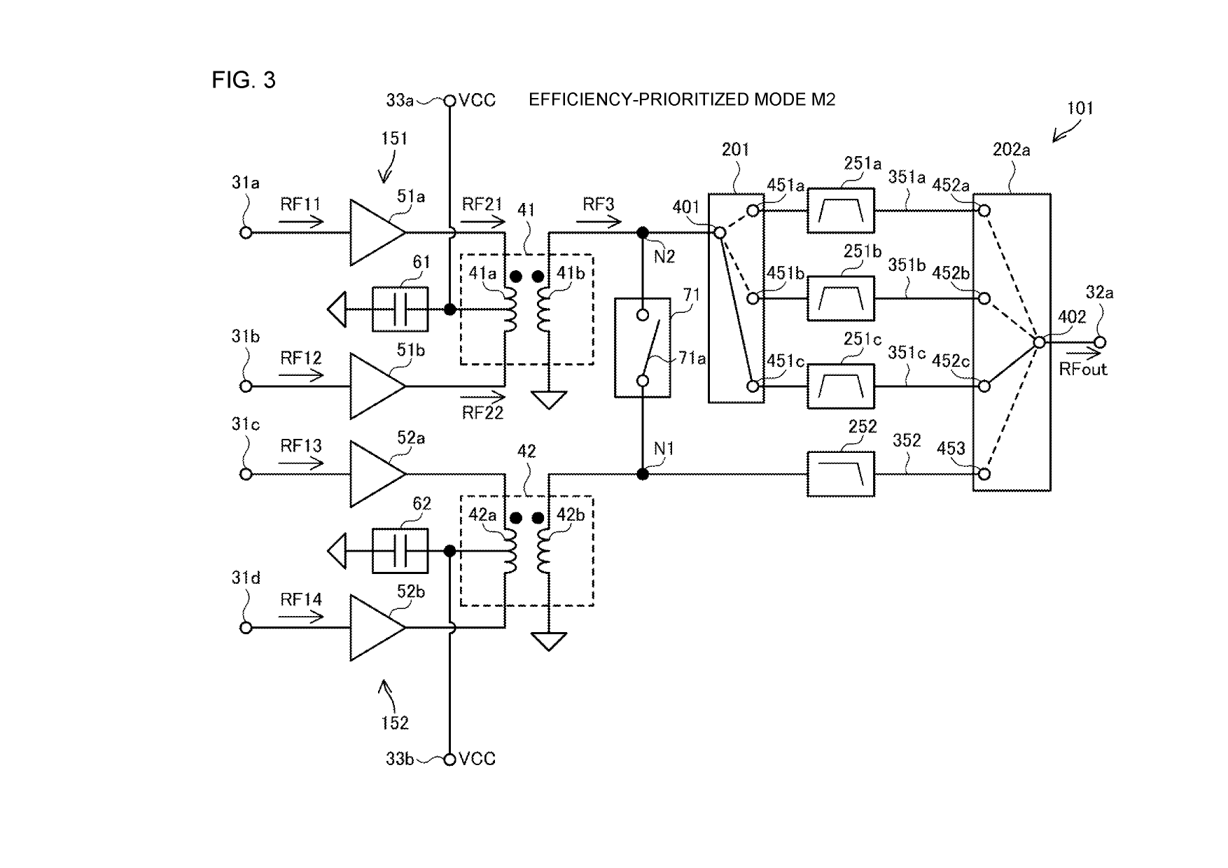

FIG. 3 is a view illustrating an example of connection states of the semiconductor switching circuits at the time when the power amplifier circuit 101 operates in the efficiency-prioritized mode M2. As illustrated in FIG. 3, the semiconductor switching element 71a does not electrically connect the first end and the second end in the efficiency-prioritized mode M2. The amplified signal RF3 may thereby be prevented from being transmitted to the inductor 42b and the individual terminal 453 via the node N1.

The semiconductor switching circuits 201 and 202a electrically connect the common terminal 401 to the common terminal 402 through one of the transmission lines 351 the number of which is M (for example, 3) in the efficiency-prioritized mode M2.

In this embodiment, in the semiconductor switching circuit 201, the common terminal 401 and the individual terminal 451c are electrically connected, and the common terminal 401 and the individual terminals 451a and 451b are not electrically connected. In the semiconductor switching circuit 202a, the common terminal 402 and the individual terminal 452c are electrically connected, and the common terminal 402 and the individual terminals 452a, 452b, and 453 are not electrically connected.

The amplified signal RF3 supplied from the first end of the inductor 41b thereby passes through the common terminal 401 and the individual terminal 451c in the semiconductor switching circuit 201, the filter circuit 251c, and the individual terminal 452c and the common terminal 402 in the semiconductor switching circuit 202a and is outputted from the output terminal 32a to the circuit at the subsequent stage, for example, the antenna.

In the power amplifier circuit 101, in the power-prioritized mode M1, the amplified signal in the 2G band obtained by combining the amplified signals RF1 and RF2 may pass through the dedicated filter circuit 252 without passing through the semiconductor switching circuit 201 and then be outputted to the output terminal 32a.

In the power amplifier circuit 101, in the efficiency-prioritized mode M2, the amplified signal RF3 in the 5G band may pass through one of the filter circuits 251 of the filter circuits 251a, 251b, and 251c that is appropriate for the frequency band of the amplified signal RF3 and then be outputted to the output terminal 32a.

The power amplifier circuit 101 is capable of amplifying a RF signal in the 2G band an RF signal in the 5G band that comply with different communication standards in the same amplifier, and thus the power amplifier circuit 101 may be downsized.

The configuration in which the common terminal 401 and the common terminal 402 are electrically connected with the filter circuit 251c interposed therebetween has heretofore been described; however, the embodiment is not limited to this configuration. A configuration in which the common terminal 401 and the common terminal 402 are electrically connected with the filter circuit 251a or 251b interposed therebetween may also be used.

### Second Embodiment

A power amplifier circuit 102 according to a second embodiment will be described. In the second embodiment and after, matters common to the first embodiment are omitted, and only different points are described. In particular, the same actions and effects of the same configuration are not referred to one by one for each embodiment.

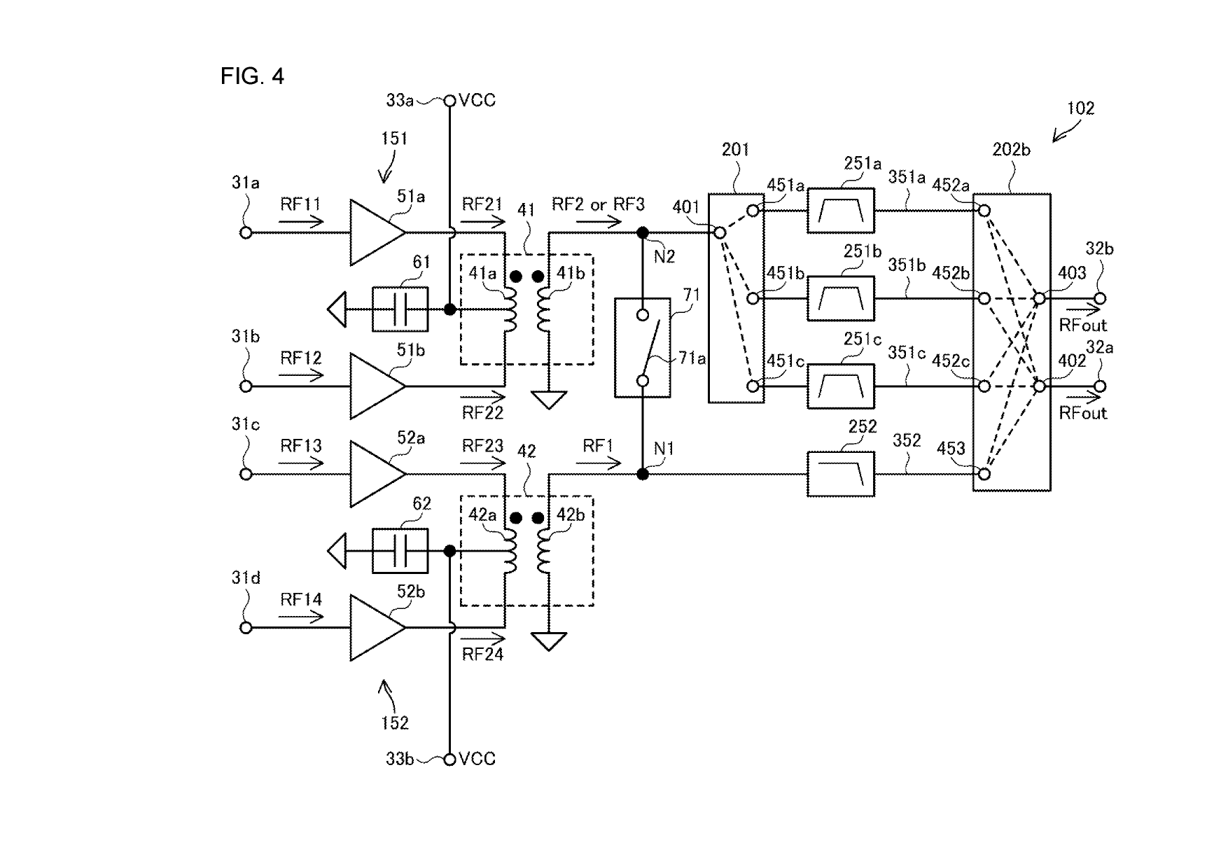

FIG. 4 is a circuit diagram of the power amplifier circuit 102. As illustrated in FIG. 4, the power amplifier circuit 102 according to the second embodiment is different from the power amplifier circuit 101 according to the first embodiment in that the output signal RFout may be outputted from one of the output terminal 32a and an output terminal 32b (second output terminal).

As compared with the power amplifier circuit 101 illustrated in FIG. 1, the power amplifier circuit 102 (filter switching circuit) includes a semiconductor switching circuit 202b (second semiconductor switching circuit), instead of the semiconductor switching circuit 202a.

As compared with the semiconductor switching circuit 202a illustrated in FIG. 1, the semiconductor switching circuit 202b further has a common terminal 403 (third common terminal) connected to the output terminal 32b.

As compared with the semiconductor switching circuit 202a illustrated in FIG. 1, the semiconductor switching circuit 202b further performs switching between electrical connection and non-connection between the common terminal 403 and any one of the individual terminals 452 the number of which is M (for example, 3) or the individual terminal 453.

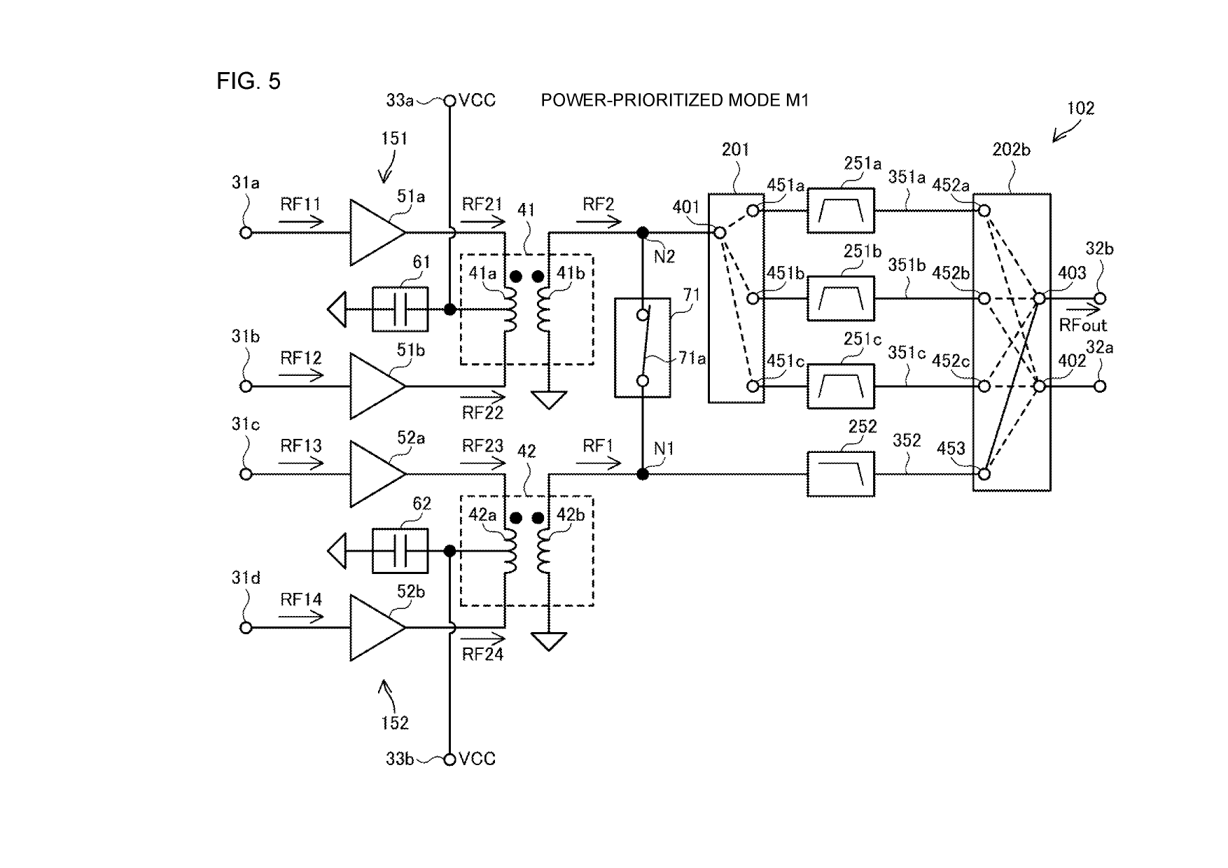

FIG. 5 is a view illustrating an example of connection states of the semiconductor switching circuits at the time when the power amplifier circuit 102 operates in the power-prioritized mode M1. As illustrated in FIG. 5, the semiconductor switching element 71a electrically connects the first end and the second end in the power-prioritized mode M1.

The semiconductor switching circuits 201 and 202b do not electrically connect the common terminal 401 and the common terminals 402 and 403 in the power-prioritized mode M1.

The semiconductor switching circuit 202b electrically connects one of the common terminals 402 and 403 and the individual terminal 453 in the power-prioritized mode M1.

In this embodiment, the semiconductor switching circuit 202b electrically connects the common terminal 403 and the individual terminal 453 in the power-prioritized mode M1.

The amplified signal combined at the node N1 thereby passes through the filter circuit 252 as well as the individual terminal 453 and the common terminal 403 in the semiconductor switching circuit 202b and is outputted from the output terminal 32b to the circuit at the subsequent stage, for example, the antenna.

In the power-prioritized mode M1, the semiconductor switching circuit 202b may electrically connect the common terminal 402 and the individual terminal 453, instead of electrically connecting the common terminal 403 and the individual terminal 453.

One of the output terminals 32a and 32b may thereby be selected as a supply target of the output signal RFout, and thus the output signal RFout may be supplied to an antenna suitable for the characteristics of the output signal RFout.

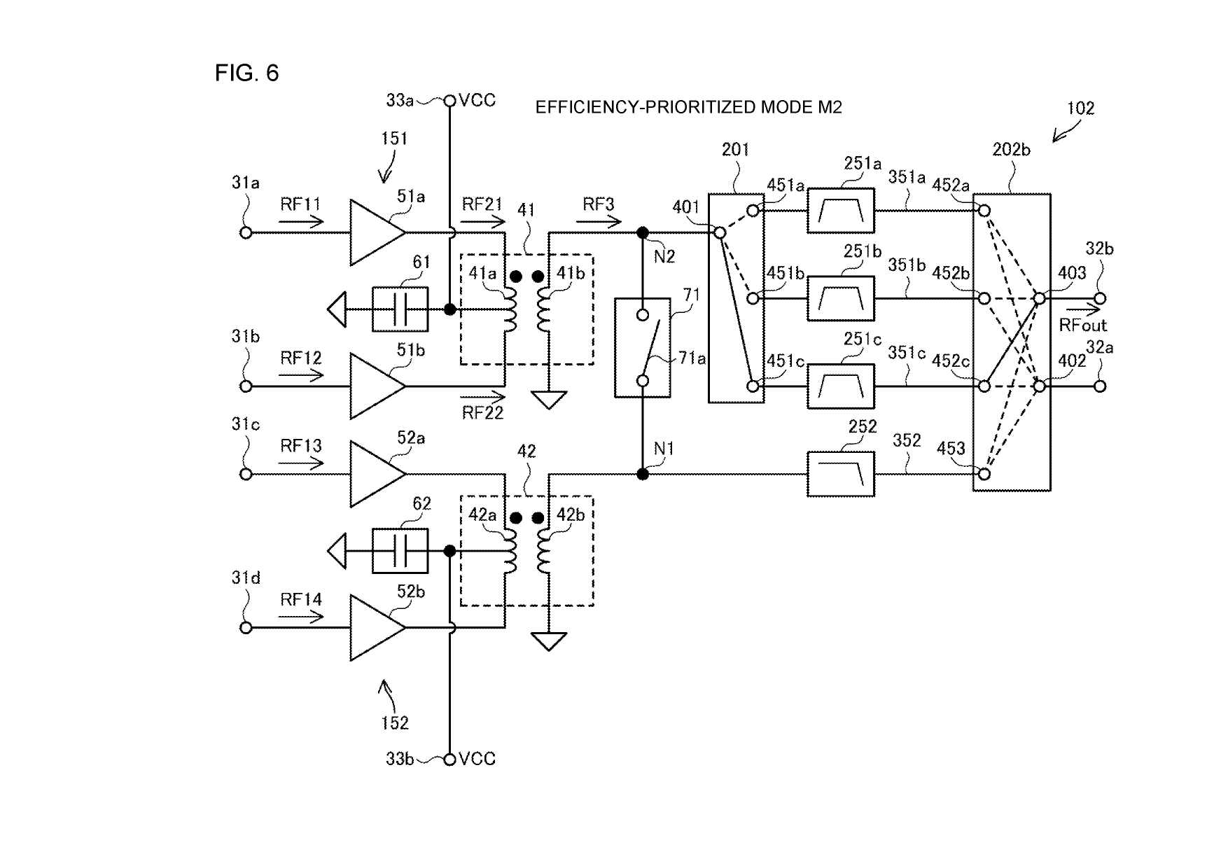

FIG. 6 is a view illustrating an example of connection states of the semiconductor switching circuits at the time when the power amplifier circuit 102 operates in the efficiency-prioritized mode M2. As illustrated in FIG. 6, the semiconductor switching element 71a does not electrically connect the first end and the second end in the efficiency-prioritized mode M2.

The semiconductor switching circuits 201 and 202b electrically connect the common terminal 401 to one of the common terminals 402 and 403 through one of the transmission lines 351 the number of which is M (for example, 3) in the efficiency-prioritized mode M2.

In this embodiment, in the semiconductor switching circuit 201, the common terminal 401 and only the individual terminal 451c are electrically connected. In the semiconductor switching circuit 202b, the common terminal 403 and only the individual terminal 452c are electrically connected.

The amplified signal RF3 supplied from the first end of the inductor 41b thereby passes through the common terminal 401 and the individual terminal 451c in the semiconductor switching circuit 201, the filter circuit 251c, and the individual terminal 452c and the common terminal 403 in the semiconductor switching circuit 202b and is outputted from the output terminal 32b to the circuit at the subsequent stage, for example, the antenna.

In the efficiency-prioritized mode M2, the semiconductor switching circuit 202b may electrically connect the common terminal 402 and the individual terminal 452c, instead of electrically connecting the common terminal 403 and the individual terminal 452c.

### Third Embodiment

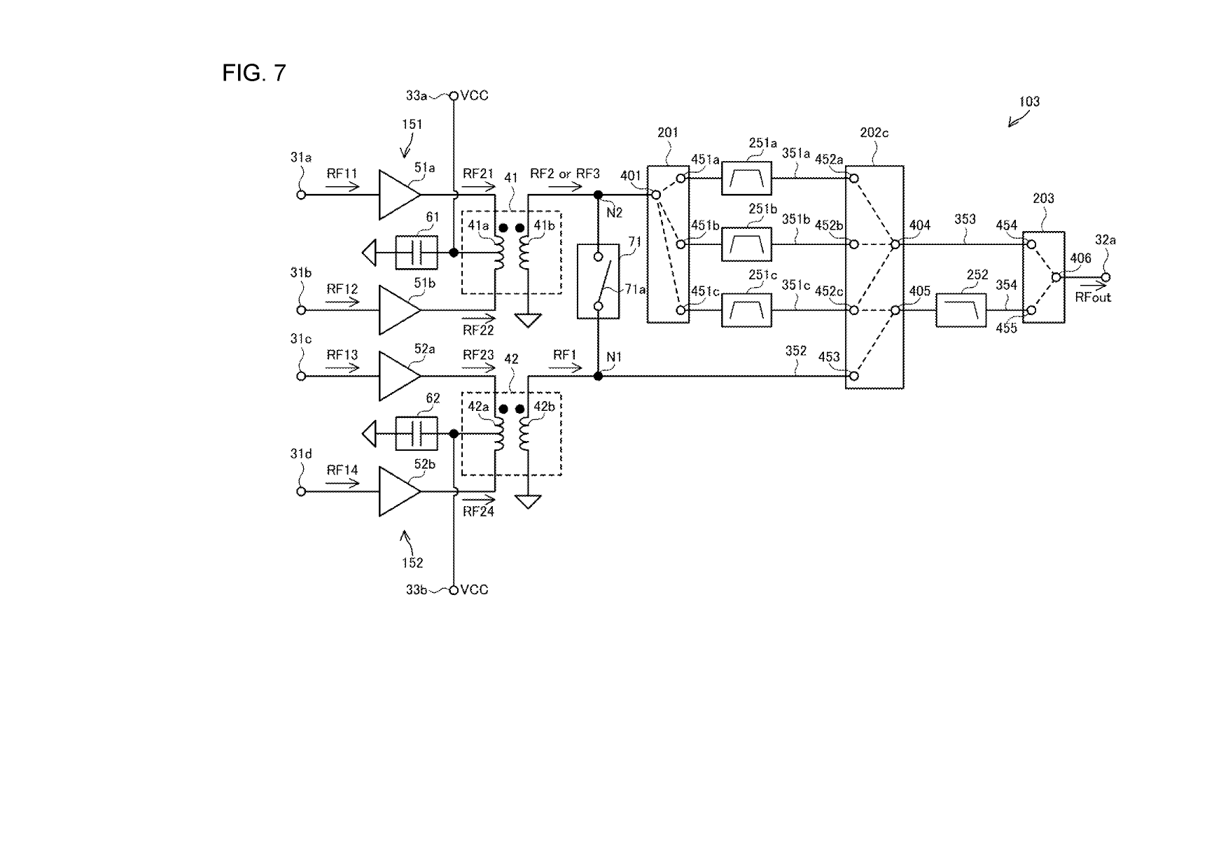

A power amplifier circuit 103 according to a third embodiment will be described. FIG. 7 is a circuit diagram of the power amplifier circuit 103. As illustrated in FIG. 7, the power amplifier circuit 103 according to the third embodiment is different from the power amplifier circuit 101 according to the first embodiment in that the amplified signal RF3 having passed through one of the filter circuits 251 is allowed to further pass through the filter circuit 252.

As compared with the power amplifier circuit 101 illustrated in FIG. 1, the power amplifier circuit 103 (filter switching circuit) includes a semiconductor switching circuit 202c (second semiconductor switching circuit) instead of the semiconductor switching circuit 202a and further includes a semiconductor switching circuit 203 (third semiconductor switching circuit).

As compared with the semiconductor switching circuit 202a illustrated in FIG. 1, the semiconductor switching circuit 202c has a common terminal 404 (fourth common terminal) connected to a transmission line 353 (third wiring line) and a common terminal 405 (fifth common terminal) connected to a transmission line 354 (fourth wiring line), instead of the common terminal 402.

The semiconductor switching circuit 202c performs switching between electrical connection and non-connection between the common terminal 404 and any one of the individual terminals 452 the number of which is M (for example, 3) and also performs switching between electrical connection and non-connection between the common terminal 405 and either at least one of the M individual terminals 452 or the individual terminal 453.

In this embodiment, the semiconductor switching circuit 202c performs switching between the electrical connection and the non-connection between the common terminal 404 and any one of the individual terminals 452a, 452b, and 452c and also performs switching between the electrical connection and the non-connection between the common terminal 405 and any one of the individual terminals 452c and 453.

The embodiment is not limited to the configuration in which the semiconductor switching circuit 202c performs switching between the electrical connection and the non-connection between the common terminal 405 and any one of the individual terminals 452c and 453, and a configuration in which the semiconductor switching circuit 202c performs switching between electrical connection and non-connection between the common terminal 405 and a subset or all of the individual terminals 452a to 452c or the individual terminal 453 may be used.

The semiconductor switching circuit 203 is provided between the semiconductor switching circuit 202c and the output terminal 32a.

The semiconductor switching circuit 203 has a common terminal 406 (sixth common terminal) connected to the output terminal 32a, an individual terminal 454 (fourth individual terminal) connected to the common terminal 404 through the transmission line 353, and an individual terminal 455 (fifth individual terminal) connected to the common terminal 405 (fifth common terminal) through the transmission line 354.

The semiconductor switching circuit 203 performs switching between electrical connection and non-connection between the common terminal 406 and any one of the individual terminals 454 and 455. The filter circuit 252 is provided on the transmission line 354.

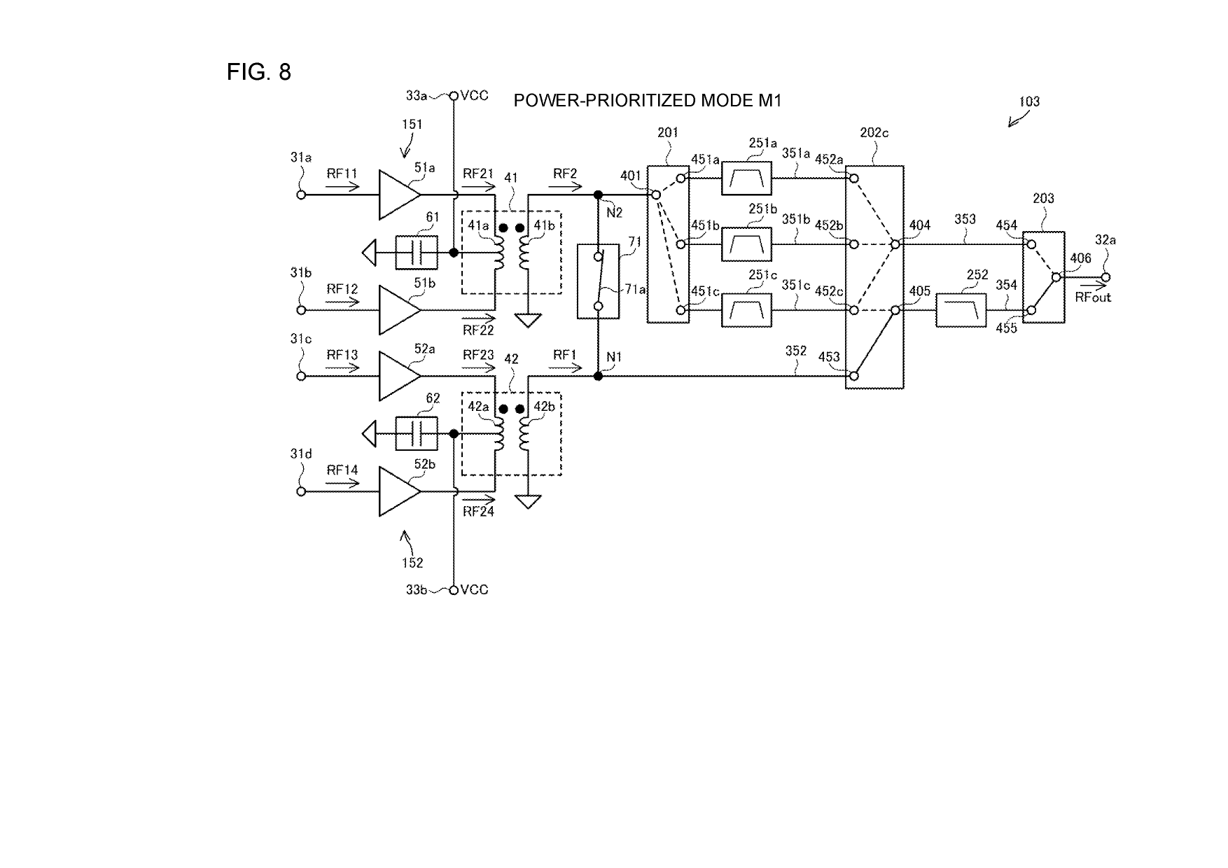

FIG. 8 is a view illustrating an example of connection states of the semiconductor switching circuits at the time when the power amplifier circuit 103 operates in the power-prioritized mode M1. As illustrated in FIG. 8, the semiconductor switching element 71a electrically connects the first end and the second end in the power-prioritized mode M1.

The semiconductor switching circuits 201 and 202c do not electrically connect the common terminal 401, the common terminal 404, and the common terminal 405 in the power-prioritized mode M1.

The semiconductor switching circuits 202c and 203 electrically connect the common terminal 406 and the individual terminal 453 through the transmission line 354 in the power-prioritized mode M1.

The amplified signal combined at the node N1 thereby passes through the individual terminal 453 and the common terminal 405 in the semiconductor switching circuit 202c, the filter circuit 252, and the individual terminal 455 and the common terminal 406 in the semiconductor switching circuit 203 and is outputted from the output terminal 32a to the circuit at the subsequent stage, for example, the antenna.

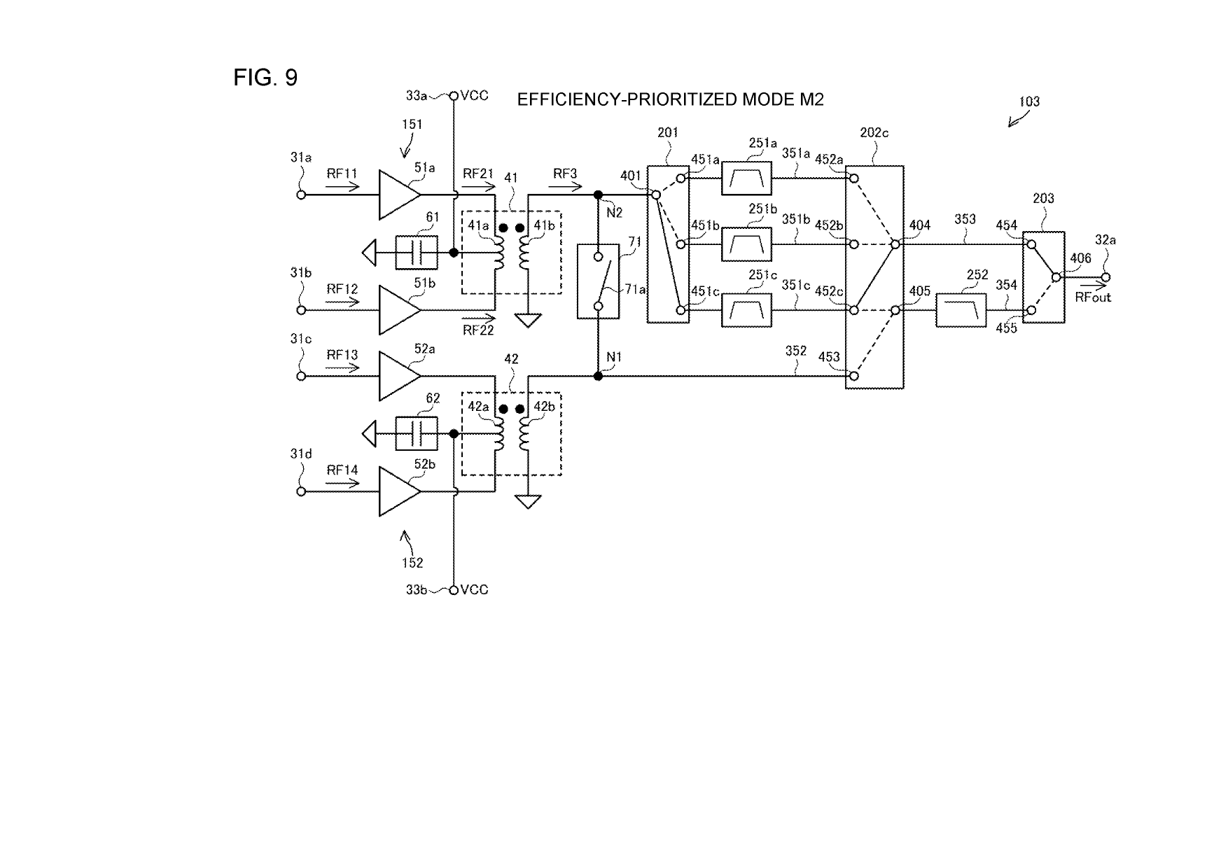

FIG. 9 is a view illustrating an example of connection states of the semiconductor switching circuits at the time when the power amplifier circuit 103 operates in the efficiency-prioritized mode M2. As illustrated in FIG. 9, the semiconductor switching element 71a does not electrically connect the first end and the second end in the efficiency-prioritized mode M2.

In the efficiency-prioritized mode M2, the semiconductor switching circuits 201, 202c, and 203 electrically connect the common terminal 401 to the common terminal 406 through one of the transmission lines 351 the number of which is M (for example, 3) and one of the transmission lines 353 and 354.

In the example illustrated in FIG. 9, in the semiconductor switching circuit 201, the common terminal 401 and only the individual terminal 451c are electrically connected. In the semiconductor switching circuit 202c, the common terminal 404 and only the individual terminal 452c are electrically connected. In the semiconductor switching circuit 203, the common terminal 406 and only the individual terminal 454 are electrically connected.

The amplified signal RF3 supplied from the first end of the inductor 41b thereby passes through the common terminal 401 and the individual terminal 451c in the semiconductor switching circuit 201, the filter circuit 251c, the individual terminal 452c and the common terminal 404 in the semiconductor switching circuit 202c, and the individual terminal 454 and the common terminal 406 in the semiconductor switching circuit 203 and is outputted from the output terminal 32a to the circuit at the subsequent stage, for example, the antenna.

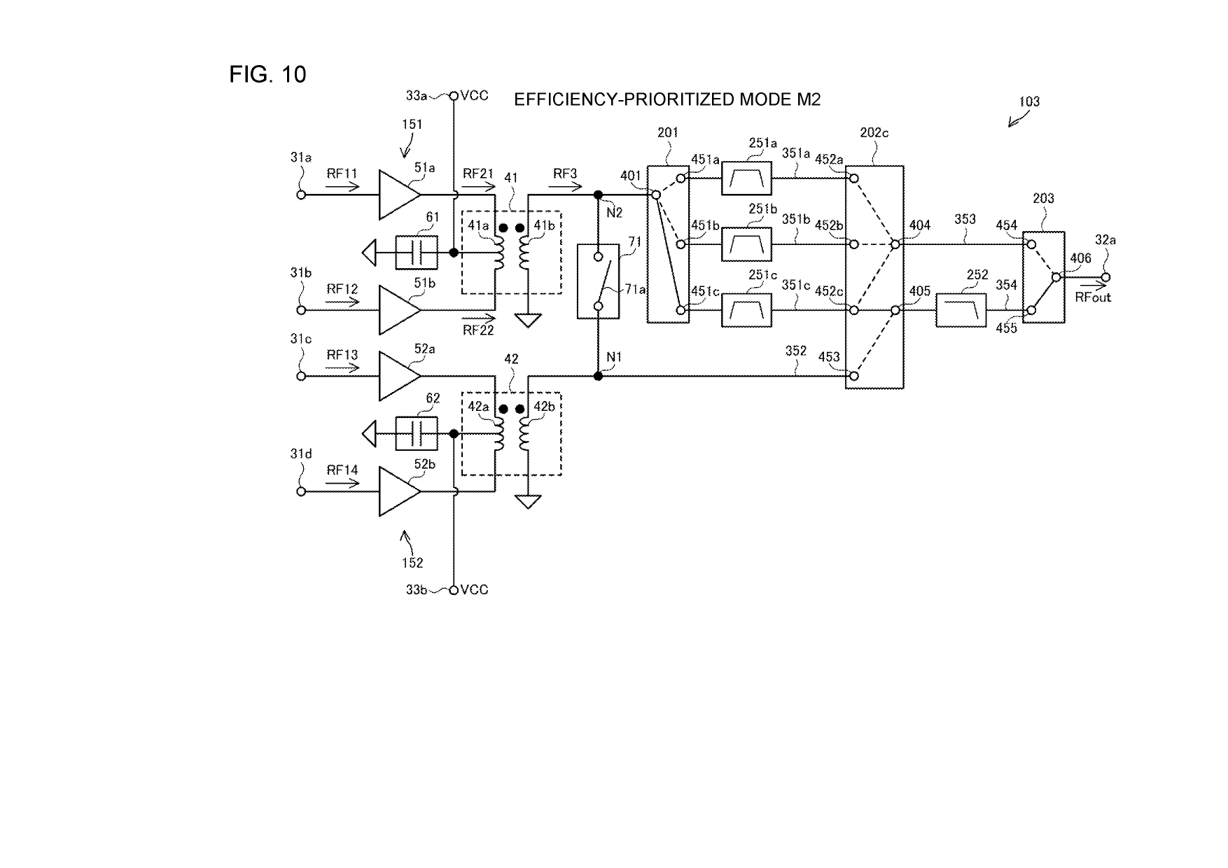

FIG. 10 is a view illustrating an example of connection states of the semiconductor switching circuits at the time when the power amplifier circuit 103 operates in the efficiency-prioritized mode M2.

As illustrated in FIG. 10, in the semiconductor switching circuit 201, the common terminal 401 and only the individual terminal 451c are electrically connected. In the semiconductor switching circuit 202c, the common terminal 405 and only the individual terminal 452c are electrically connected. In the semiconductor switching circuit 203, the common terminal 406 and only the individual terminal 455 are electrically connected.

The amplified signal RF3 supplied from the first end of the inductor 41b thereby passes through the common terminal 401 and the individual terminal 451c in the semiconductor switching circuit 201, the filter circuit 251c, the individual terminal 452c and the common terminal 405 in the semiconductor switching circuit 202c, the filter circuit 252, and the individual terminal 455 and the common terminal 406 in the semiconductor switching circuit 203 and is outputted from the output terminal 32a to the circuit at the subsequent stage, for example, the antenna.

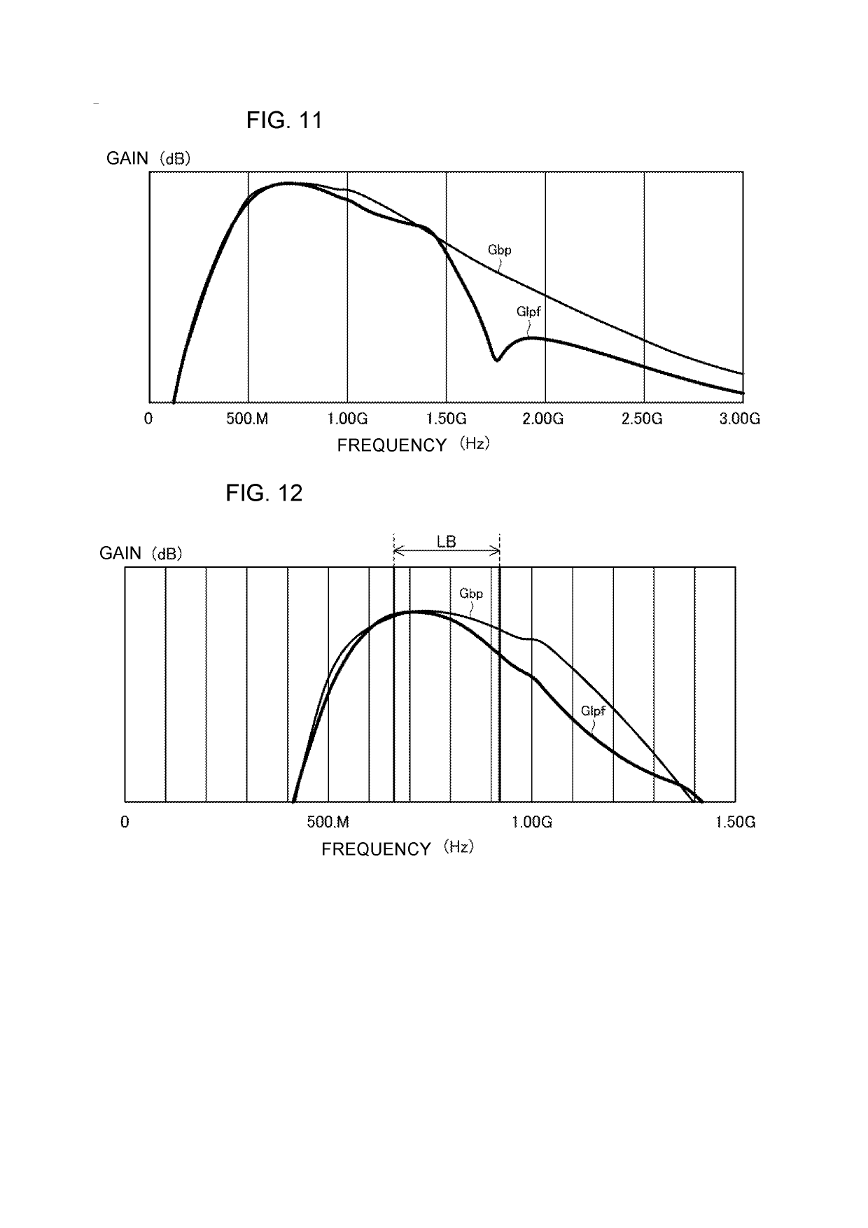

FIG. 11 is a graph illustrating an example of simulation results of amplification characteristics in the power amplifier circuit 103. The vertical axis represents gain in units of dB. The horizontal axis represents frequency in units of Hz.

FIG. 12 is an enlarged graph of the amplification characteristics at zero to 1.5 GHz in the simulation results illustrated in FIG. 11. The form of FIG. 12 is the same as that of FIG. 11.

As illustrated in FIGS. 11 and 12, a curve Glpf represents changes in gain and frequency at the time when the amplified signal RF3 is outputted to the output terminal 32b via the filter circuit 252 that is the low pass filter (see FIG. 10).

A curve Gbp represents changes in gain and frequency at the time when the amplified signal RF3 is outputted to the output terminal 32b through the transmission line 353 that is the bypass path (see FIG. 9).

In a case where reduced harmonic wave power is required for the amplified signal RF3 in the 5G band, the switch connection states as illustrated in FIG. 10 enables the amplified signal RF3 to pass through the filter circuit 252 used for the RF signal in the 2G band. A gain around 1.75 GHz that is a harmonic wave band may thereby be reduced, as represented by the curve Glpf. The harmonic wave power may be reduced.

In a case where reduced harmonic wave power is not required for the amplified signal RF3 in the 5G band, the switch connection states as illustrated in FIG. 9 enables the amplified signal RF3 to pass through the transmission line 353 and bypass the filter circuit 252. A decrease in gain in the low band (LB) from 660 MHz to 920 MHz (see FIG. 12) may thereby be reduced, as represented by the curve Gbp. The amplified signal RF3 may thus be outputted to the output terminal 32a with high efficiency.

For this embodiment, the configuration in which the amplified signal RF3 passes through one of the transmission line 353 and the filter circuit 252 has heretofore been described; however, the embodiment is not limited to this configuration. A configuration in which the amplified signal RF3 passes through the transmission line 353 and the filter circuit 252 may be used.

### Fourth Embodiment

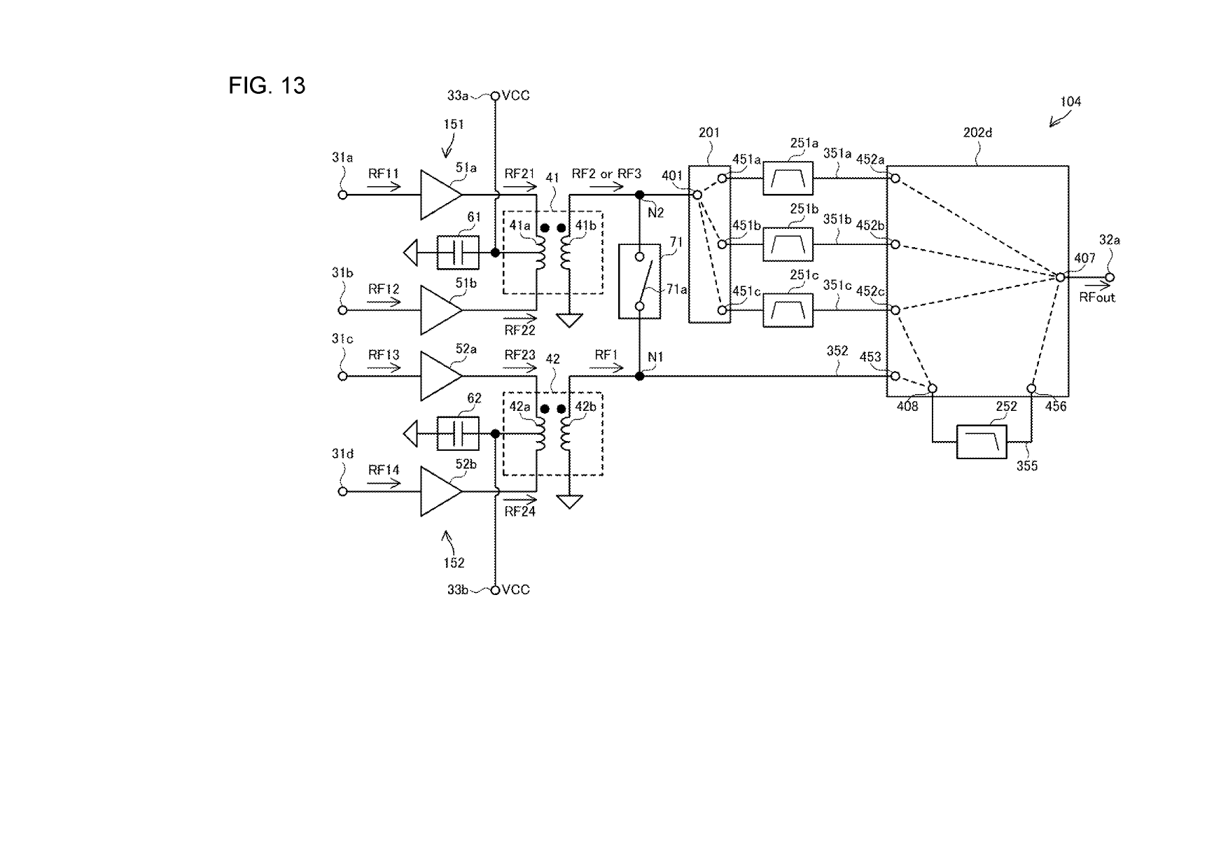

A power amplifier circuit 104 according to a fourth embodiment will be described. FIG. 13 is a circuit diagram of the power amplifier circuit 104. As illustrated in FIG. 13, the power amplifier circuit 104 according to the fourth embodiment is different from the power amplifier circuit 103 according to the third embodiment in that the semiconductor switching circuits 202c and 203 are integrated into one semiconductor switching circuit.

As compared with the power amplifier circuit 103 illustrated in FIG. 7, the power amplifier circuit 104 (filter switching circuit) includes a semiconductor switching circuit 202d (second semiconductor switching circuit) instead of the semiconductor switching circuits 202c and 203.

As compared with the semiconductor switching circuit 202c illustrated in FIG. 7, the semiconductor switching circuit 202d has a common terminal 407 (seventh common terminal) connected to the output terminal 32a, an individual terminal 456 (sixth individual terminal), and a common terminal 408 (eighth common terminal) connected to the individual terminal 456 through a transmission line 355 (fifth wiring line), instead of the common terminal 404 and the common terminal 405. The filter circuit 252 is provided on the transmission line 355.

The semiconductor switching circuit 202d performs switching between electrical connection and non-connection between the common terminal 407 and any one of the individual terminals 452 the number of which is M (for example, 3) or the individual terminal 456 and also performs switching between electrical connection and non-connection between the common terminal 408 and either at least one of the M individual terminals 452 or the individual terminal 453.

In this embodiment, the semiconductor switching circuit 202d performs switching between electrical connection and non-connection between the common terminal 407 and any one of the individual terminals 452a, 452b, 452c, and 456 and also performs switching between electrical connection and non-connection between the common terminal 408 and any one of the individual terminals 452c and 453.

The embodiment is not limited to the configuration in which the semiconductor switching circuit 202d performs switching between the electrical connection and the non-connection between the common terminal 408 and any one of the individual terminals 452c and 453, and a configuration in which the semiconductor switching circuit 202d performs switching between electrical connection and non-connection between the common terminal 408 and a subset or all of the individual terminals 452a to 452c or the individual terminal 453 may be used.

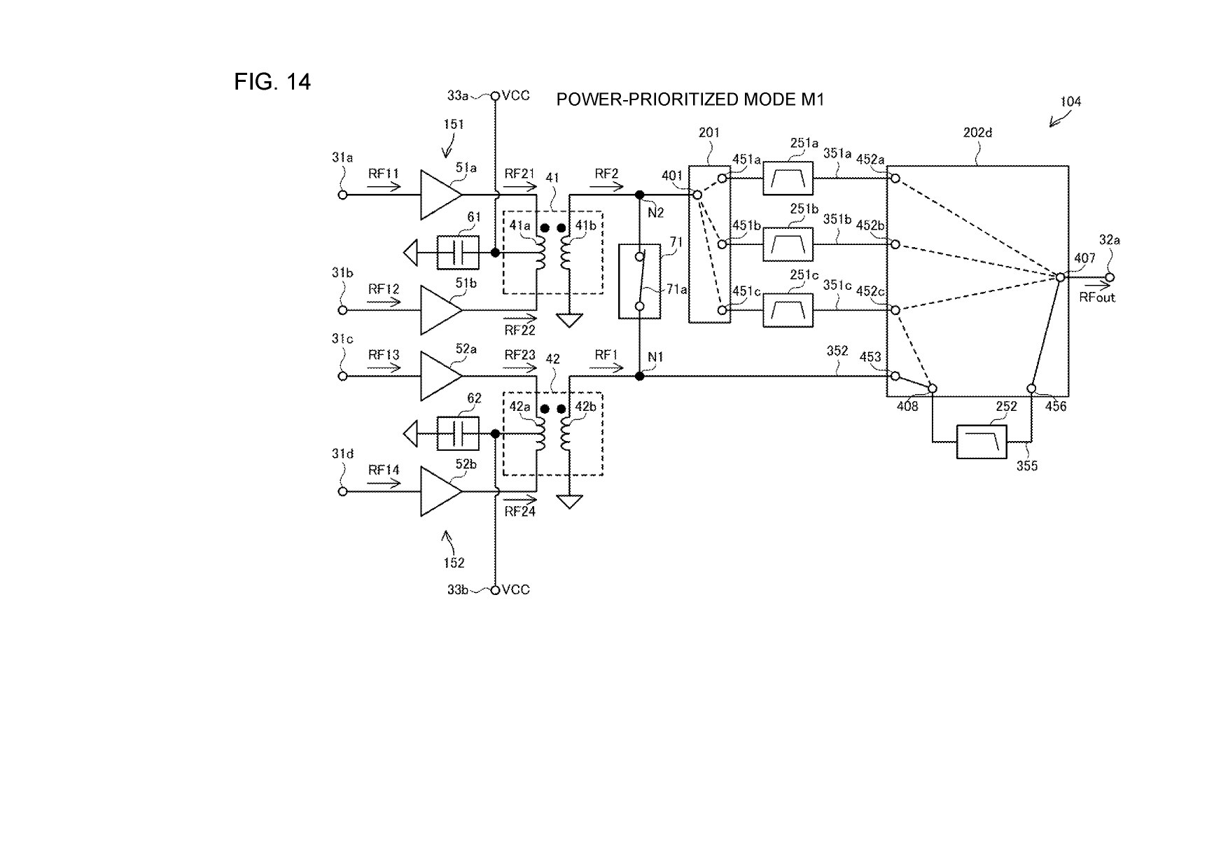

FIG. 14 is a view illustrating an example of connection states of the semiconductor switching circuits at the time when the power amplifier circuit 104 operates in the power-prioritized mode M1. As illustrated in FIG. 14, the semiconductor switching element 71a electrically connects the first end and the second end in the power-prioritized mode M1.

The semiconductor switching circuits 201 and 202d do not electrically connect the common terminal 401, the common terminal 407, and the common terminal 408 in the power-prioritized mode M1.

The semiconductor switching circuit 202d electrically connects the common terminal 407 and the individual terminal 453 through the transmission line 355 in the power-prioritized mode M1.

Specifically, in the semiconductor switching circuit 202d, electrical connection is performed between the common terminal 407 and the individual terminal 456 and between the common terminal 408 and only the individual terminal 453.

The amplified signal combined at the node N1 thereby passes through the individual terminal 453 and the common terminal 408 in the semiconductor switching circuit 202d, the filter circuit 252, and the individual terminal 456 and the common terminal 407 in the semiconductor switching circuit 202d and is outputted from the output terminal 32a to the circuit at the subsequent stage, for example, the antenna.

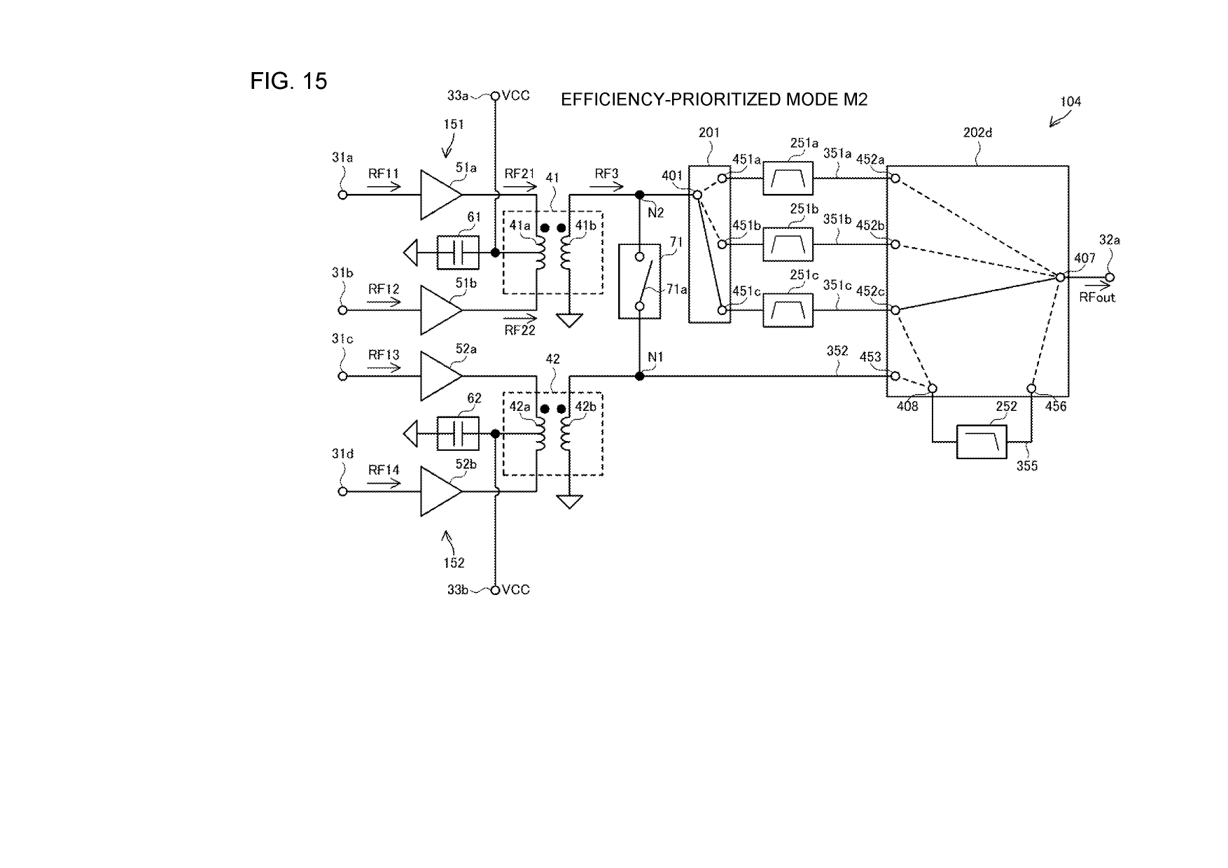

FIG. 15 is a view illustrating an example of connection states of the semiconductor switching circuits at the time when the power amplifier circuit 104 operates in the efficiency-prioritized mode M2. As illustrated in FIG. 15, the semiconductor switching element 71a does not electrically connect the first end and the second end in the efficiency-prioritized mode M2.

In the efficiency-prioritized mode M2, the semiconductor switching circuits 201 and 202d electrically connect the common terminal 401 to the common terminal 407 through one of the transmission lines 351 the number of which is M (for example, 3) but not through the transmission line 355.

In the example illustrated in FIG. 15, in the semiconductor switching circuit 201, the common terminal 401 and only the individual terminal 451c are electrically connected. In the semiconductor switching circuit 202d, the common terminal 407 and only the individual terminal 452c are electrically connected.

The amplified signal RF3 supplied from the first end of the inductor 41b thereby passes through the common terminal 401 and the individual terminal 451c in the semiconductor switching circuit 201, the filter circuit 251c, and the individual terminal 452c and the common terminal 407 in the semiconductor switching circuit 202d and is outputted from the output terminal 32a to the circuit at the subsequent stage, for example, the antenna.

That is, as compared with the example illustrated in FIG. 9, the number of switches through which the amplified signal RF3 passes may be reduced, and thus power reduction in the amplified signal RF3 may be reduced. In addition, as compared with the power amplifier circuit 103 illustrated in FIG. 7, the number of semiconductor switching circuits may be reduced. The semiconductor switching circuit is formed on, for example, an IC chip, and thus the power amplifier circuit 104 may be downsized.

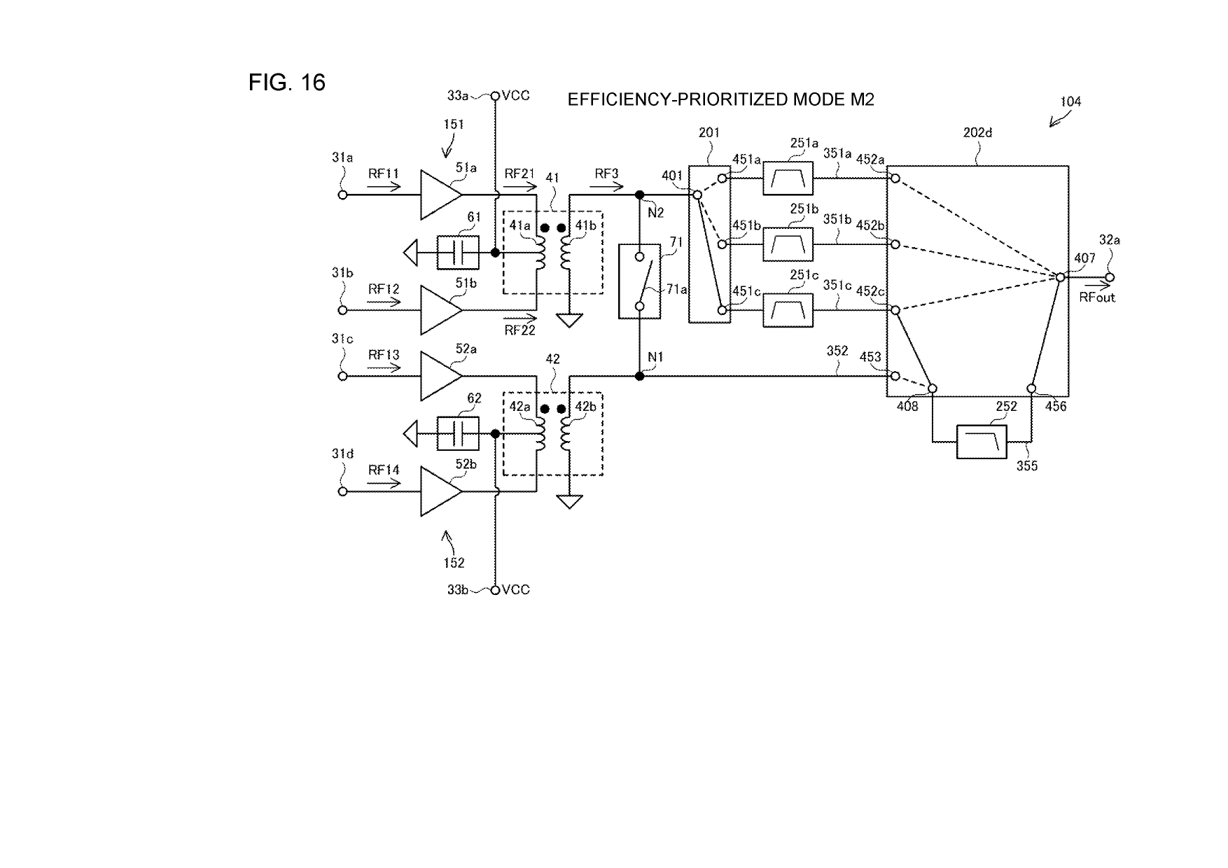

FIG. 16 is a view illustrating an example of connection states of the semiconductor switching circuits at the time when the power amplifier circuit 104 operates in the efficiency-prioritized mode M2.

As illustrated in FIG. 16, in the efficiency-prioritized mode M2, the semiconductor switching circuits 201 and 202d electrically connect the common terminal 401 to the common terminal 407 through one of the M transmission lines 351 and the transmission line 355.

In the example illustrated in FIG. 16, in the semiconductor switching circuit 201, the common terminal 401 and only the individual terminal 451c are electrically connected. In the semiconductor switching circuit 202d, electrical connection is performed between the common terminal 407 and the individual terminal 456 and between the common terminal 408 and only the individual terminal 452c.

The amplified signal RF3 supplied from the first end of the inductor 41b thereby passes through the common terminal 401 and the individual terminal 451c in the semiconductor switching circuit 201, the filter circuit 251c, the individual terminal 452c and the common terminal 408 in the semiconductor switching circuit 202d, the filter circuit 252, and the individual terminal 456 and the common terminal 407 in the semiconductor switching circuit 202d and is outputted from the output terminal 32a to the circuit at the subsequent stage, for example, the antenna.

For this embodiment, the configuration in which the amplified signal RF3 passes through one of the filter circuits 251a, 251b, and 251c has heretofore been described; however, the embodiment is not limited to this configuration. A configuration in which the amplified signal RF3 passes through two or more of the filter circuits 251a, 251b, and 251c may be used.

For this embodiment, the configuration in which the differential pairs 151 and 152 are provided at the previous stage of the nodes N1 and N2 has heretofore been described; but the embodiment is not limited to this configuration. A configuration in which a Doherty amplifier circuit is provided at the previous stage of the nodes N1 and N2 may be used.

Exemplary embodiments of the present disclosure have heretofore been described. In the power amplifier circuits 101 and 102, the amplified signal RF1 in the 2G band is supplied to the node N1 in the power-prioritized mode M1. The amplified signal RF2 in the 2G band having the same phase as that of the amplified signal RF1 is supplied to the node N2 in the power-prioritized mode M1, and the amplified signal RF3 in the 5G band is supplied in the efficiency-prioritized mode M2. The semiconductor switching element 71a has the first end connected to the node N1 and the second end connected to the node N2 and performs switching between the electrical connection and the non-connection between the first end and the second end. The semiconductor switching circuit 201 has the common terminal 401 connected to the node N2 and the individual terminals 451 the number of which is M (the integer of 2 or greater) and performs switching between the electrical connection and the non-connection between the common terminal 401 and any one of the M individual terminals 451. The semiconductor switching circuits 202a and 202b have the common terminal 402 connected to the output terminal 32a, the M individual terminals 452 respectively connected to the M individual terminals 451 through the M transmission lines 351, and the individual terminal 453 connected to the node N1 through the transmission line 352. The semiconductor switching circuits 202a and 202b each perform the switching between the electrical connection and the non-connection between the common terminal 402 and any one of the M individual terminals 452 or the individual terminal 453. The M filter circuits 251 are respectively provided on the M transmission lines 351. The filter circuit 252 is provided on the transmission line 352.

With the configuration as described above, a signal path from the node N2 to the output terminal 32a via the semiconductor switching circuit 201, at least one filter circuit 251 of the M filter circuits 251, and the semiconductor switching circuit 202a may be established. In addition, a signal path from the node N1 to the output terminal 32a via the dedicated filter circuit 252 and the semiconductor switching circuit 202a may be established not via the semiconductor switching circuit 201. Power loss in an amplified signal in passing through the semiconductor switching circuit 201 on the signal path from the node N1 to the output terminal 32a may thereby be reduced. Power loss in a radio frequency signal may thus be reduced.

In the power amplifier circuit 101, the semiconductor switching element 71a electrically connects the first end and the second end in the power-prioritized mode M1. The semiconductor switching circuits 201 and 202a do not electrically connect the common terminal 401 and the common terminal 402 in the power-prioritized mode M1. The semiconductor switching circuit 202a electrically connects the common terminal 402 and the individual terminal 453 in the power-prioritized mode M1.

With the configuration as described above, in the power-prioritized mode M1, the amplified signals RF1 and RF2 may be combined at the node N1, and the amplified signal thus combined may be outputted to the output terminal 32a via the filter circuit 252 and the semiconductor switching circuit 202a. In addition, the amplified signal RF2 may be prevented from being supplied to the output terminal 32a via the semiconductor switching circuits 201 and 202a.

In the power amplifier circuit 101, the semiconductor switching element 71a does not electrically connect the first end and the second end in the efficiency-prioritized mode M2. The semiconductor switching circuits 201 and 202a electrically connect the common terminal 401 to the common terminal 402 through one of the M transmission lines 351 in the efficiency-prioritized mode M2.

With the configuration as described above, in the efficiency-prioritized mode M2, the semiconductor switching circuit 201 may perform switching of the output destination of the amplified signal RF3 to one of the M filter circuits 251 that is appropriate for the frequency band of the amplified signal RF3. With the configuration in which the semiconductor switching element 71a does not electrically connect the first end and the second end, the amplified signal RF3 may be prevented from being supplied to the output terminal 32a via the filter circuit 252 and the semiconductor switching circuit 202a.

In the power amplifier circuit 102, the semiconductor switching circuit 202b further has the common terminal 403 connected to the output terminal 32b. The semiconductor switching circuit 202b further performs switching between electrical connection and non-connection between the common terminal 403 and any one of the M individual terminals 452 or the individual terminal 453.

With the configuration as described above, one of the output terminals 32a and 32b may be selected as the output destination of the amplified signal that passes through at least one of the M filter circuits 251 and the filter circuit 252 and that is inputted to the semiconductor switching circuit 202a. The amplified signal may thereby be supplied to, for example, an antenna conforming to the frequency band of the amplified signal or the communication standard.

In the power amplifier circuit 103, the amplified signal RF1 in the 2G band is supplied to the node N1 in the power-prioritized mode M1. The amplified signal RF2 in the 2G band having the same phase as that of the amplified signal RF1 is supplied to the node N2 in the power-prioritized mode M1, and the amplified signal RF3 in the 5G band is supplied in the efficiency-prioritized mode M2. The semiconductor switching element 71a has the first end connected to the node N1 and the second end connected to the node N2 and performs switching between the electrical connection and the non-connection between the first end and the second end. The semiconductor switching circuit 201 has the common terminal 401 connected to the node N2 and the individual terminals 451 the number of which is M (the integer of 2 or greater) and performs switching between the electrical connection and the non-connection between the common terminal 401 and any one of the M individual terminals 451. The semiconductor switching circuit 202c has the common terminal 404 connected to the transmission line 353, the M individual terminals 452 respectively connected to the M individual terminals 451 through the M transmission lines 351, and the individual terminal 453 connected to the node N1 through the transmission line 352, and the common terminal 405 connected to the transmission line 354 and performs switching between the electrical connection and the non-connection between the common terminal 404 and any one of the M individual terminals 452 and also performs switching between the electrical connection and the non-connection between the common terminal 405 and either at least one of the M individual terminals 452 or the individual terminal 453. The M filter circuits 251 are respectively provided on the M transmission lines 351. The filter circuit 252 is provided on the transmission line 354.

With the configuration as described above, the signal path from the node N2 to at least one of the transmission line 353 and the dedicated filter circuit 252 via the semiconductor switching circuit 201, at least one of the M filter circuits 251, and the semiconductor switch circuit 202c may be established. The signal path from the node N1 to the dedicated filter circuit 252 via the semiconductor switching circuit 202c, not via the semiconductor switching circuit 201, may also be established. Power loss in an amplified signal in passing through the semiconductor switching circuit 201 on the signal path from the node N1 to the filter circuit 252 may thereby be reduced. Power loss in a radio frequency signal may thus be reduced.

In the power amplifier circuit 103, the semiconductor switching circuit 203 is provided between the semiconductor switching circuit 202c and the output terminal 32a. The semiconductor switching circuit 203 has the common terminal 406 connected to the output terminal 32a, the individual terminal 454 connected to the common terminal 404 through the transmission line 353, and the individual terminal 455 connected to the common terminal 405 through the transmission line 354. The semiconductor switching circuit 203 performs switching between the electrical connection and the non-connection between the common terminal 406 and any one of the individual terminals 454 and 455.

With the configuration as described above, the signal path from the respective common terminals 404 and 405 to the output terminal 32a via the transmission line 353 and the filter circuit 252 may be established. Regardless of whether the amplified signal passes through the transmission line 353 or the filter circuit 252, the amplified signal may thereby be supplied to the one output terminal 32a.

In the power amplifier circuit 102, the semiconductor switching element 71a electrically connects the first end and the second end in the power-prioritized mode M1. The semiconductor switching circuits 201 and 202c do not electrically connect the common terminal 401 and the common terminals 404 and 405 in the power-prioritized mode M1. The semiconductor switching circuits 202c and 203 electrically connect the common terminal 406 and the individual terminal 453 through the transmission line 354 in the power-prioritized mode M1.

With the configuration as described above, in the power-prioritized mode M1, the amplified signals RF1 and RF2 may be combined at the node N1, and the amplified signal thus combined may be outputted to the output terminal 32a via the semiconductor switching circuit 202c, the filter circuit 252, and the semiconductor switching circuit 203. In addition, the amplified signal RF2 may be prevented from being supplied to the output terminal 32a via the semiconductor switching circuits 201 and 202c.

In the power amplifier circuit 103, the semiconductor switching element 71a does not electrically connect the first end and the second end in the efficiency-prioritized mode M2. In the efficiency-prioritized mode M2, the semiconductor switching circuits 201, 202c, and 203 electrically connect the common terminal 401 to the common terminal 406 via one of the M transmission lines 351 and one of the transmission lines 353 and 354.

With the configuration as described above, in the efficiency-prioritized mode M2, the semiconductor switching circuit 201 may perform switching of the output destination of the amplified signal RF3 to one of the M filter circuits 251 that is appropriate for the frequency band of the amplified signal RF3. The amplified signal RF3 having passed through one of the filter circuits 251 is caused to further pass through the filter circuit 252 or caused to pass through the transmission line 353 that bypasses the filter circuit 252 and thereby may be outputted to the output terminal 32a. With the configuration in which the semiconductor switching element 71a does not electrically connect the first end and the second end, the amplified signal RF3 may be prevented from being supplied to the output terminal 32a via the semiconductor switching circuit 202c, the filter circuit 252, and the semiconductor switching circuit 203.

In the power amplifier circuit 104, the amplified signal RF1 in the 2G band is supplied to the node N1 in the power-prioritized mode M1. The amplified signal RF2 in the 2G band having the same phase as that of the amplified signal RF1 is supplied to the node N2 in the power-prioritized mode M1, and the amplified signal RF3 in the 5G band is supplied in the efficiency-prioritized mode M2. The semiconductor switching element 71a has the first end connected to the node N1 and the second end connected to the node N2 and performs switching between the electrical connection and the non-connection between the first end and the second end. The semiconductor switching circuit 201 has the common terminal 401 connected to the node N2 and the individual terminals 451 the number of which is M (the integer of 2 or greater) and performs switching between the electrical connection and the non-connection between the common terminal 401 and any one of the M individual terminals 451. The semiconductor switching circuit 202d has the common terminal 407 connected to the output terminal 32a, the M individual terminals 452 respectively connected to the M individual terminals 451 through the M transmission lines 351, the individual terminal 453 connected to the node N1 through the transmission line 352, the individual terminal 456, and the common terminal 408 connected to the individual terminal 456 through the transmission line 355. The semiconductor switching circuit 202d performs switching between the electrical connection and the non-connection between the common terminal 407 and any one of the M individual terminals 452 or the individual terminal 456 and also performs switching between the electrical connection and the non-connection between the common terminal 408 and either at least one of the M individual terminals 452 or the individual terminal 453. The M filter circuits 251 are respectively provided on the M transmission lines 351. The filter circuit 252 is provided on the transmission line 355.

With the configuration as described above, the signal path from the node N2 to the output terminal 32a via the semiconductor switching circuit 201, the at least one filter circuit 251 of the M filter circuits 251, and the semiconductor switching circuit 202d may be established. The signal path from the node N1 to the output terminal 32a via the semiconductor switching circuit 202d, the dedicated filter circuit 252, and the semiconductor switching circuit 202d, not via the semiconductor switching circuit 201, may also be established. Power loss in an amplified signal in passing through the semiconductor switching circuit 201 on the signal path from the node N1 to the output terminal 32a may thereby be reduced. Power loss in a radio frequency signal may thus be reduced.

In the power amplifier circuit 104, the semiconductor switching element 71a electrically connects the first end and the second end in the power-prioritized mode M1. The semiconductor switching circuits 201 and 202d do not electrically connect the common terminal 401 and the common terminals 407 and 408 in the power-prioritized mode M1. The semiconductor switching circuit 202d electrically connects the common terminal 407 and the individual terminal 453 through the transmission line 355 in the power-prioritized mode M1.

With the configuration as described above, in the power-prioritized mode M1, the amplified signals RF1 and RF2 may be combined at the node N1, and the amplified signal thus combined may be outputted to the output terminal 32a via the semiconductor switching circuit 202d, the filter circuit 252, and the semiconductor switching circuit 202d. The amplified signal RF2 may also be prevented from being supplied to the output terminal 32a via the semiconductor switching circuits 201 and 202d.

In the power amplifier circuit 104, the semiconductor switching element 71a does not electrically connect the first end and the second end in the efficiency-prioritized mode M2. In the efficiency-prioritized mode M2, the semiconductor switching circuits 201 and 202d electrically connect the common terminal 401 to the common terminal 407 via one of the M transmission lines 351, not via the transmission line 355.

With the configuration as described above, in the efficiency-prioritized mode M2, the semiconductor switching circuit 201 may perform switching of the output destination of the amplified signal RF3 to one of the M filter circuits 251 that is appropriate for the frequency band of the amplified signal RF3. The amplified signal RF3 having passed through one of the filter circuits 251 is caused to bypass the filter circuit 252 in the semiconductor switching circuit 202d and thereby may be outputted to the output terminal 32a. With the configuration in which the semiconductor switching element 71a does not electrically connect the first end and the second end, the amplified signal RF3 may be prevented from being supplied to the output terminal 32a via the semiconductor switching circuit 202d, the filter circuit 252, and the semiconductor switching circuit 202d.

In the power amplifier circuit 104, the semiconductor switching element 71a does not electrically connect the first end and the second end in the efficiency-prioritized mode M2. In the efficiency-prioritized mode M2, the semiconductor switching circuits 201 and 202d electrically connect the common terminal 401 to the common terminal 407 via one of the M transmission lines 351 and the transmission line 355.

With the configuration as described above, in the efficiency-prioritized mode M2, the semiconductor switching circuit 201 may perform switching of the output destination of the amplified signal RF3 to one of the M filter circuits 251 that is appropriate for the frequency band of the amplified signal RF3. The amplified signal RF3 having passed through one of the filter circuits 251 is caused to further pass through the filter circuit 252 by performing switching of a path in the semiconductor switching circuit 202d and may thereby be outputted to the output terminal 32a. With the configuration in which the semiconductor switching element 71a does not electrically connect the first end and the second end, the amplified signal RF3 may be prevented from being supplied to the output terminal 32a via the semiconductor switching circuit 202d, the filter circuit 252, and the semiconductor switching circuit 202d.

The embodiments described above have been provided for easier understanding of the present disclosure and are not intended to limit the interpretation of the present disclosure. The present disclosure may be changed/improved without departing from the spirit thereof and includes its equivalents. That is, any of the embodiments subjected to a designing change appropriately by those skilled in the art is included in the scope of the present disclosure as long as the changed embodiment has the feature of the present disclosure. For example, the components of each embodiment, the arrangement, the material, the condition, the shape, the size of each component are not limited to those exemplified and may be changed appropriately. It goes without saying that each embodiment is an example and the configuration described in the embodiment may be partially replaced or combined with that in a different one of the embodiments. These are included in the scope of the present disclosure, as long as these have the feature of the present disclosure.

(1) A filter switching circuit includes: a first node supplied with a first amplified signal in a first radio frequency band in a first mode; a second node that is supplied, in the first mode, with a second amplified signal in the first radio frequency band having a phase identical to a phase of the first amplified signal and that is supplied, in a second mode, with a third amplified signal in a second radio frequency band; a semiconductor switching element including a first end connected to the first node and a second end connected to the second node, the semiconductor switching element performing switching between electrical connection and non-connection between the first end and the second end; a first semiconductor switching circuit including a first common terminal connected to the second node and first individual terminals a count of which is M (an integer of 2 or greater), the first semiconductor switching circuit performing switching between electrical connection and non-connection between the first common terminal and any one of the M first individual terminals; a second semiconductor switching circuit including a second common terminal connected to a first output terminal, M second individual terminals respectively connected to the M first individual terminals through M first wiring lines, and a third individual terminal connected to the first node through a second wiring line, the second semiconductor switching circuit performing switching between electrical connection and non-connection between the second common terminal and any one of the M second individual terminals or the third individual terminal; M first filters respectively provided on the M first wiring lines; and a second filter provided on the second wiring line.

(2) In the filter switching circuit according to (1), in the first mode, the semiconductor switching element electrically connects the first end and the second end, in the first mode, the first semiconductor switching circuit and the second semiconductor switching circuit do not electrically connect the first common terminal and the second common terminal, and in the first mode, the second semiconductor switching circuit electrically connects the second common terminal and the third individual terminal.

(3) In the filter switching circuit according to (1) or (2), in the filter switching circuit according to (1), in the second mode, the semiconductor switching element does not electrically connect the first end and the second end, and in the second mode, the first semiconductor switching circuit and the second semiconductor switching circuit electrically connect the first common terminal to the second common terminal through one of the M first wiring lines.

(4) In the filter switching circuit according to any one of (1) to (3), in the filter switching circuit according to (1), the second semiconductor switching circuit further includes a third common terminal connected to a second output terminal and further performs switching between electrical connection and non-connection between the third common terminal and any one of the M second individual terminals or the third individual terminal.

(5) A filter switching circuit includes: a first node supplied with a first amplified signal in a first radio frequency band in a first mode; a second node that is supplied, in the first mode, with a second amplified signal in the first radio frequency band having a phase identical to a phase of the first amplified signal and that is supplied, in a second mode, with a third amplified signal in a second radio frequency band; a semiconductor switching element including a first end connected to the first node and a second end connected to the second node, the semiconductor switching element performing switching between electrical connection and non-connection between the first end and the second end; a first semiconductor switching circuit including a first common terminal connected to the second node and first individual terminals a count of which is M (an integer of 2 or greater), the first semiconductor switching circuit performing switching between electrical connection and non-connection between the first common terminal and any one of the M first individual terminals; a second semiconductor switching circuit including a fourth common terminal connected to a third wiring line, M second individual terminals respectively connected to the M first individual terminals through M first wiring lines, a third individual terminal connected to the first node through a second wiring line, a fifth common terminal connected to a fourth wiring line, the second semiconductor switching circuit performing switching between electrical connection and non-connection between the fourth common terminal and any one of the M second individual terminals, the second semiconductor switching circuit also performing switching between electrical connection and non-connection between the fifth common terminal and either at least one of the M second individual terminals or the third individual terminal; M first filters respectively provided on the M first wiring lines; and a second filter provided on the fourth wiring line.

(6) In the filter switching circuit according to (5), the filter switching circuit according to (5) further includes: a third semiconductor switching circuit including a sixth common terminal provided between the second semiconductor switching circuit and a first output terminal and connected to the first output terminal, a fourth individual terminal connected to the fourth common terminal through the third wiring line, and a fifth individual terminal connected to the fifth common terminal through the fourth wiring line, the third semiconductor switching circuit performing switching between electrical connection and non-connection between the sixth common terminal and either the fourth individual terminal or the fifth individual terminal.

(7) In the filter switching circuit according to (6), in the first mode, the semiconductor switching element electrically connects the first end and the second end, in the first mode, the first semiconductor switching circuit and the second semiconductor switching circuit do not electrically connect the first common terminal, the fourth common terminal, and the fifth common terminal, and in the first mode, the second semiconductor switching circuit and the third semiconductor switching circuit electrically connect the sixth common terminal and the third individual terminal through the fourth wiring line.

(8) In the filter switching circuit according to (6) or (7), in the filter switching circuit according to (6), in the second mode, the semiconductor switching element does not electrically connect the first end and the second end, and in the second mode, the first semiconductor switching circuit, the second semiconductor switching circuit, and the third semiconductor switching circuit electrically connect the first common terminal to the sixth common terminal through one of the M first wiring lines and either the third wiring line or the fourth wiring line.

(9) A filter switching circuit includes: a first node supplied with a first amplified signal in a first radio frequency band in a first mode; a second node that is supplied, in the first mode, with a second amplified signal in the first radio frequency band having a phase identical to a phase of the first amplified signal and that is supplied, in a second mode, with a third amplified signal in a second radio frequency band; a semiconductor switching element including a first end connected to the first node and a second end connected to the second node, the semiconductor switching element performing switching between electrical connection and non-connection between the first end and the second end; a first semiconductor switching circuit including a first common terminal connected to the second node and first individual terminals a count of which is M (an integer of 2 or greater), the first semiconductor switching circuit performing switching between electrical connection and non-connection between the first common terminal and any one of the M first individual terminals; a second semiconductor switching circuit including a seventh common terminal connected to a first output terminal, M second individual terminals respectively connected to the M first individual terminals through M first wiring lines, a third individual terminal connected to the first node through a second wiring line, a sixth individual terminal, an eighth common terminal connected to the sixth individual terminal through a fifth wiring line, the second semiconductor switching circuit performing switching between electrical connection and non-connection between the seventh common terminal and any one of the M second individual terminals or the sixth individual terminal, the second semiconductor switching circuit also performing switching between electrical connection and non-connection between the eighth common terminal and either at least one of the M second individual terminals or the third individual terminal; M first filters respectively provided on the M first wiring lines; and a second filter provided on the fifth wiring line.

(10) In the filter switching circuit according to (9), in the first mode, the semiconductor switching element electrically connects the first end and the second end, in the first mode, the first semiconductor switching circuit and the second semiconductor switching circuit do not electrically connect the first common terminal, the seventh common terminal, and the eighth common terminal, and in the first mode, the second semiconductor switching circuit electrically connects the seventh common terminal and the third individual terminal through the fifth wiring line.

(11) In the filter switching circuit according to (9) or (10), in the second mode, the semiconductor switching element does not electrically connect the first end and the second end, and in the second mode, the first semiconductor switching circuit and the second semiconductor switching circuit electrically connect the first common terminal to the seventh common terminal through one of the M first wiring lines, not through the fifth wiring line.

(12) In the filter switching circuit according to any one of (9) to (11), in the second mode, the semiconductor switching element does not electrically connect the first end and the second end, and in the second mode, the first semiconductor switching circuit and the second semiconductor switching circuit electrically connect the first common terminal to the seventh common terminal through one of the M first wiring lines and the fifth wiring line.

(13) In the filter switching circuit according to any one of (1) to (12), the first mode and the second mode are respectively a power-prioritized mode and an efficiency-prioritized mode.

What is claimed is:

1. A filter switching circuit comprising:
a first node that is supplied with a first amplified signal in a first radio frequency band when the filter switching circuit operates in a first mode;
a second node that is supplied, when the filter switching circuit operates in the first mode, with a second amplified signal in the first radio frequency band having a phase identical to a phase of the first amplified signal and that is supplied, when the filter switching circuit operates in a second mode, with a third amplified signal in a second radio frequency band;
a semiconductor switch having a first end connected to the first node and a second end connected to the second node, the semiconductor switch being configured to switch between electrical connection and non-connection between the first end and the second end;
a first semiconductor switching circuit comprising a first common terminal connected to the second node and M first individual terminals, M being an integer greater than or equal to 2, the first semiconductor switching circuit being configured to switch between electrical connection and non-connection between the first common terminal and any one of the first individual terminals;
a second semiconductor switching circuit comprising a second common terminal connected to a first output terminal, M second individual terminals respectively connected to the M first individual terminals through M first wiring lines, and a third individual terminal connected to the first node through a second wiring line, the second semiconductor switching circuit being configured to switch between electrical connection and non-connection between the second common terminal and any one of the M second individual terminals or the third individual terminal;
M first filters respectively provided on the M first wiring lines; and
a second filter provided on the second wiring line.

2. The filter switching circuit according to claim 1,
wherein when the filter switching circuit operates in the first mode, the semiconductor switch is configured to electrically connect the first end and the second end,
wherein when the filter switching circuit operates in the first mode, the first semiconductor switching circuit and the second semiconductor switching circuit are configured to not electrically connect the first common terminal and the second common terminal, and
wherein when the filter switching circuit operates in the first mode, the second semiconductor switching circuit is configured to electrically connect the second common terminal and the third individual terminal.

3. The filter switching circuit according to claim 1,
wherein when the filter switching circuit operates in the second mode, the semiconductor switch is configured to not electrically connect the first end and the second end, and
wherein when the filter switching circuit operates in the second mode, the first semiconductor switching circuit and the second semiconductor switching circuit are configured to electrically connect the first common terminal to the second common terminal through one of the M first wiring lines.

4. The filter switching circuit according to claim 1,
wherein the second semiconductor switching circuit further comprises a third common terminal connected to a second output terminal, and is further configured to switch between electrical connection and non-connection between the third common terminal and any one of the M second individual terminals or the third individual terminal.

5. A filter switching circuit comprising:
a first node that is supplied with a first amplified signal in a first radio frequency band when the filter switching circuit operates in a first mode;
a second node that is supplied, when the filter switching circuit operates in the first mode, with a second amplified signal in the first radio frequency band having a phase identical to a phase of the first amplified signal, and that is supplied, when the filter switching circuit operates in a second mode, with a third amplified signal in a second radio frequency band;
a semiconductor switch having a first end connected to the first node and a second end connected to the second node, the semiconductor switch being configured to switch between electrical connection and non-connection between the first end and the second end;
a first semiconductor switching circuit comprising a first common terminal connected to the second node and M first individual terminals, M being an integer greater than or equal to 2, the first semiconductor switching circuit being configured to switch between electrical connection and non-connection between the first common terminal and any one of the M first individual terminals;
a second semiconductor switching circuit comprising a fourth common terminal connected to a third wiring line, M second individual terminals respectively connected to the M first individual terminals through M first wiring lines, a third individual terminal connected to the first node through a second wiring line, and a fifth common terminal connected to a fourth wiring line, the second semiconductor switching circuit being configured to switch between electrical connection and non-connection between the fourth common terminal and any one of the M second individual terminals, and being configured to switch between electrical connection and non-connection between the fifth common terminal and either at least one of the M second individual terminals or the third individual terminal;
M first filters respectively provided on the M first wiring lines; and
a second filter on the fourth wiring line.

6. The filter switching circuit according to claim 5, further comprising:
a third semiconductor switching circuit comprising a sixth common terminal between the second semiconductor switching circuit and a first output terminal and connected to the first output terminal, a fourth individual terminal connected to the fourth common terminal through the third wiring line, and a fifth individual terminal connected to the fifth common terminal through the fourth wiring line, the third semiconductor switching circuit being configured to switch between electrical connection and non-connection between the sixth common terminal and either the fourth individual terminal or the fifth individual terminal.

7. The filter switching circuit according to claim 6,
wherein when the filter switching circuit operates in the first mode, the semiconductor switch is configured to electrically connect the first end and the second end,
wherein when the filter switching circuit operates in the first mode, the first semiconductor switching circuit and the second semiconductor switching circuit are configured to not electrically connect the first common terminal, the fourth common terminal, and the fifth common terminal, and
wherein when the filter switching circuit operates in the first mode, the second semiconductor switching circuit and the third semiconductor switching circuit are configured to electrically connect the sixth common terminal and the third individual terminal through the fourth wiring line.

8. The filter switching circuit according to claim 6,
wherein when the filter switching circuit operates in the second mode, the semiconductor switch is configured to not electrically connect the first end and the second end, and
wherein when the filter switching circuit operates in the second mode, the first semiconductor switching circuit, the second semiconductor switching circuit, and the third semiconductor switching circuit are configured to electrically connect the first common terminal to the sixth common terminal through one of the M first wiring lines and either the third wiring line or the fourth wiring line.

9. A filter switching circuit comprising:
a first node that is supplied with a first amplified signal in a first radio frequency band when the filter switching circuit operates in a first mode;
a second node that is supplied, when the filter switching circuit operates in the first mode, with a second amplified signal in the first radio frequency band having a phase identical to a phase of the first amplified signal, and that is supplied, when the filter switching circuit operates in a second mode, with a third amplified signal in a second radio frequency band;
a semiconductor switch having a first end connected to the first node and a second end connected to the second node, the semiconductor switch being configured to switch between electrical connection and non-connection between the first end and the second end;
a first semiconductor switching circuit comprising a first common terminal connected to the second node and M first individual terminals, M being an integer greater than or equal to 2, the first semiconductor switching circuit being configured to switch between electrical connection and non-connection between the first common terminal and any one of the M first individual terminals;
a second semiconductor switching circuit comprising a seventh common terminal connected to a first output terminal, M second individual terminals respectively connected to the M first individual terminals through M first wiring lines, a third individual terminal connected to the first node through a second wiring line, a sixth individual terminal, and an eighth common terminal connected to the sixth individual terminal through a fifth wiring line, the second semiconductor switching circuit being configured to switch between electrical connection and non-connection between the seventh common terminal and any one of the M second individual terminals or the sixth individual terminal, and being configured to switch between electrical connection and non-connection between the eighth common terminal and either at least one of the M second individual terminals or the third individual terminal;
M first filters respectively provided on the M first wiring lines; and
a second filter provided on the fifth wiring line.

10. The filter switching circuit according to claim 9,
wherein when the filter switching circuit operates in the first mode, the semiconductor switch is configured to electrically connect the first end and the second end,
wherein when the filter switching circuit operates in the first mode, the first semiconductor switching circuit and the second semiconductor switching circuit are configured to not electrically connect the first common terminal, the seventh common terminal, and the eighth common terminal, and
wherein when the filter switching circuit operates in the first mode, the second semiconductor switching circuit is configured to electrically connect the seventh common terminal and the third individual terminal through the fifth wiring line.

11. The filter switching circuit according to claim 9,
wherein when the filter switching circuit operates in the second mode, the semiconductor switch is configured to not electrically connect the first end and the second end, and
wherein when the filter switching circuit operates in the second mode, the first semiconductor switching circuit and the second semiconductor switching circuit are configured to electrically connect the first common terminal to the seventh common terminal through one of the M first wiring lines, not through the fifth wiring line.

12. The filter switching circuit according to claim 9,
wherein when the filter switching circuit operates in the second mode, the semiconductor switch is configured to not electrically connect the first end and the second end, and
wherein when the filter switching circuit operates in the second mode, the first semiconductor switching circuit and the second semiconductor switching circuit are configured to electrically connect the first common terminal to the seventh common terminal through one of the M first wiring lines and the fifth wiring line.

13. The filter switching circuit according to claim 1, wherein the first mode and the second mode are respectively a power-prioritized mode and an efficiency-prioritized mode.

14. The filter switching circuit according to claim 5, wherein the first mode and the second mode are respectively a power-prioritized mode and an efficiency-prioritized mode.

15. The filter switching circuit according to claim 9, wherein the first mode and the second mode are respectively a power-prioritized mode and an efficiency-prioritized mode.
